(19) United States
(12) Patent Application Publication
(10) Pub. No.: US 2020/0126790 A1
(43) Pub. Date: Apr. 23, 2020

(54) OXIDE SINTERED MATERIAL AND METHOD OF MANUFACTURING THE SAME, SPUTTERING TARGET, OXIDE SEMICONDUCTOR FILM, AND METHOD OF MANUFACTURING SEMICONDUCTOR DEVICE

(71) Applicant: Sumitomo Electric Industries, Ltd., Osaka-shi (JP)

(72) Inventors: Miki MIYANAGA, Osaka-shi (JP); Kenichi WATATANI, Osaka-shi (JP); Hideaki AWATA, Osaka-shi (JP); Aiko TOMINAGA, Osaka-shi (JP); Kazuya TOKUDA, Osaka-shi (JP)

(73) Assignee: Sumitomo Electric Industries, Ltd., Osaka-shi (JP)

(21) Appl. No.: 16/606,296

(22) PCT Filed: May 1, 2018
(86) PCT No.: PCT/JP2018/017453

§ 371 Date: Oct. 18, 2019

(30) Foreign Application Priority Data
May 16, 2017 (JP) 2017-097405
Dec. 4, 2017 (JP) PCT/JP2017/043425

(51) Int. Cl. H01L 21/02; C23C 14/34; C23C 14/08; H01L 29/786; C04B 35/453; C04B 35/495

(52) U.S. Cl. CPC H01L 21/02631; C23C 14/3407; H01L 21/02565; C04B 35/495; C23C 14/083; H01L 29/7869; C04B 35/453; C23C 14/086

(57) ABSTRACT

There are provided an oxide sintered material and a method of manufacturing the same as well as an oxide semiconductor film. The oxide sintered material contains In, W and Zn, includes an In₂O₃ crystal phase and an In₂(ZnO)ₘO₃ crystal phase (m represents a natural number), and an average number of oxygen atoms coordinated to an indium atom is 3 or more and less than 5.5. The oxide semiconductor film contains In, W and Zn. The oxide semiconductor film is amorphous, and an average number of oxygen atoms coordinated to an indium atom is 2 or more and less than 4.5.

The present application claims the benefit of priority to Japanese patent application No. 2017-097405 filed on May 16, 2017 and the international application PCT/JP2017/043425 filed on Dec. 4, 2017. The entire contents of the Japanese patent application and the international application are incorporated herein by reference.

### TECHNICAL FIELD

The present invention relates to an oxide sintered material and a method of manufacturing the same, a sputtering target, an oxide semiconductor film, and a method of manufacturing a semiconductor device.

### BACKGROUND ART

Conventionally, an amorphous silicon (a-Si) film has been mainly used as a semiconductor film which functions as a channel layer of a semiconductor device such as a TFT (thin film transistor) in a liquid crystal display device, a thin film EL (electroluminescence) display device, an organic EL display device or the like.

In recent years, as a material to replace a-Si, attention has been focused on a complex oxide containing indium (In), gallium (Ga) and zinc (Zn), in other words, an In—Ga—Zn-based complex oxide (also referred to as “IGZO”). It is expected that such IGZO-based oxide semiconductor will have a higher carrier mobility than that in a-Si.

For example, Japanese Patent Laying-Open No. 2008-199005 (PTL 1) discloses that an oxide semiconductor film mainly composed of IGZO is formed by a sputtering method using an oxide sintered material as a target.

Japanese Patent Laying-open No. 2008-192721 (PTL 2) discloses an oxide sintered material containing In and tungsten (W) as a material suitably used for forming an oxide semiconductor film by a sputtering method or the like.

Moreover, Japanese Patent Laying-open No. 09-071860 (PTL 3) discloses an oxide sintered material containing In and Zn.

### CITATION LIST

### Patent Literature

PTL 1: Japanese Patent Laying-open No. 2008-199005

PTL 2: Japanese Patent Laying-open No. 2008-192721

PTL 3: Japanese Patent Laying-open No. 09-071860

### SUMMARY OF INVENTION

According to an aspect of the present invention, an oxide sintered material contains In, W and Zn, and includes an In₂O₃ crystal phase and an In₂(ZnO)ₘO₃ crystal phase (m represents a natural number). The average number of oxygen atoms coordinated to an indium atom is 3 or more and less than 5.5.

According to another aspect of the present invention, a spattering target includes the oxide sintered material described above.

According to still another aspect of the present invention, a method of manufacturing a semiconductor device including an oxide semiconductor film includes: preparing the sputtering target described above; and forming the oxide semiconductor film by a sputtering method using the sputtering target.

According to still another aspect of the present invention, an oxide semiconductor film contains In, W and Zn, and is amorphous. In the oxide semiconductor film, the average number of oxygen atoms coordinated to an indium atom is 2 or more and less than 4.5.

According to still another aspect of the present invention, a method of manufacturing an oxide sintered material is a method of manufacturing the above-mentioned oxide sintered material in accordance with one aspect of the present invention and includes forming the oxide sintered material by sintering a molded body containing indium, tungsten and zinc. Forming the oxide sintered material includes placing the molded body for 2 hours or more in an atmosphere having an oxygen concentration not lower than that in the air at a first temperature lower than the maximum temperature in forming the oxide sintered material, and the first temperature is 300° C. or more and less than 600° C.

### BRIEF DESCRIPTION OF DRAWINGS

FIG. 1A is a schematic plan view illustrating an exemplary semiconductor device according to an embodiment of the present invention;

FIG. 1B is a schematic cross-sectional view taken along a line IB-IB illustrated in FIG. 1A;

FIG. 2 is a schematic cross-sectional view illustrating another exemplary semiconductor device according to an embodiment of the present invention;

FIG. 3 is a schematic cross-sectional view illustrating still another exemplary semiconductor device according to an embodiment of the present invention;

FIG. 4A is a schematic cross-sectional view illustrating an exemplary method of manufacturing the semiconductor device illustrated in FIGS. 1A and 1B;

FIG. 4B is a schematic cross-sectional view illustrating an exemplary method of manufacturing the semiconductor device illustrated in FIGS. 1A and 1B;

FIG. 4C is a schematic cross-sectional view illustrating an exemplary method of manufacturing the semiconductor device illustrated in FIGS. 1A and 1B;

FIG. 4D is a schematic cross-sectional view illustrating an exemplary method of manufacturing the semiconductor device illustrated in FIGS. 1A and 1B;

FIG. 5A is a schematic cross-sectional view illustrating an exemplary method of manufacturing the semiconductor device illustrated in FIG. 2;

FIG. 5B is a schematic cross-sectional view illustrating an exemplary method of manufacturing the semiconductor device illustrated in FIG. 2;

FIG. 5C is a schematic cross-sectional view illustrating an exemplary method of manufacturing the semiconductor device illustrated in FIG. 2; and

FIG. 5D is a schematic cross-sectional view illustrating an exemplary method of manufacturing the semiconductor device illustrated in FIG. 2.

### DETAILED DESCRIPTION

<Problem to be Solved by Present Disclosure>

As described in PTL 1, the TFT which includes the IGZO-based oxide semiconductor film as a channel layer has such a problem that the field-effect mobility thereof is as low as about 10 cm²/Vs.

Although PTL 2 proposes a TFT which includes, as a channel layer, an oxide semiconductor film formed by using an oxide sintered material containing In and W, no investigation has been made on the reliability of the TFT under light irradiation.

The thin film formed by using the oxide sintered material described in PTL 3 is a transparent conductive film which has a lower electrical resistance than the semiconductor thin film used as a channel layer of a TFT, for example.

In a sputtering method using an oxide sintered material as a sputtering target, it is desired to reduce the number of abnormal discharges during sputtering.

An object of the present invention is to provide an oxide sintered material containing In, W and Zn, which is capable of reducing the number of abnormal discharges during sputtering and capable of making excellent the characteristics of a semiconductor device including an oxide semiconductor film that is formed by using a sputtering target including the oxide sintered material.

Another object of the present invention is to provide a method of manufacturing the oxide sintered material capable of producing the oxide sintered material even at a lower sintering temperature.

Still another object is to provide a sputtering target including the oxide sintered material and a method of manufacturing a semiconductor device including an oxide semiconductor film formed by using the sputtering target.

Still another object is to provide an oxide semiconductor film which is capable of making excellent the characteristics of a semiconductor device when it is used as a channel layer in the semiconductor device.

<Advantageous Effect of the Present Disclosure>

According to the description in the above, it is possible to provide an oxide sintered material containing In, W and Zn, which is capable of reducing the number of abnormal discharges during sputtering and capable of making excellent the characteristics of a semiconductor device including an oxide semiconductor film that is formed by using a sputtering target including the oxide sintered material.

According to the description in the above, it is possible to provide a method of manufacturing the oxide sintered material capable of producing the oxide sintered material even at a lower sintering temperature.

According to the description in the above, it is possible to provide a sputtering target including the oxide sintered material and a method of manufacturing a semiconductor device including an oxide semiconductor film formed by using the sputtering target.

According to the description in the above, it is possible to provide an oxide semiconductor film which is capable of making excellent the characteristics of a semiconductor device when it is used as a channel layer in the semiconductor device.

### DESCRIPTION OF EMBODIMENTS

First, embodiments of the present invention will be enumerated and described hereinafter.

[1] An oxide sintered material according to an embodiment of the present invention contains In, W and Zn, includes an In₂O₃ crystal phase and an In₂(ZnO)ₘO₃ crystal phase (m represents a natural number), and the average number of oxygen atoms coordinated to an indium atom is at least 3 and less than 5.5.

According to the oxide sintered material, it is possible to reduce the number of abnormal discharges during sputtering, and it is possible to make excellent the characteristics of a semiconductor device including an oxide semiconductor film that is formed by using a sputtering target including the oxide sintered material. The oxide sintered material according to the present embodiment may be suitably used as a sputtering target for forming an oxide semiconductor film (such as an oxide semiconductor film serving as a channel layer) included in a semiconductor device.

[2] In the oxide sintered material according to the present embodiment, the content of the In₂O₃ crystal phase is preferably 10 mass % or more and less than 98 mass %, which is advantageous in reducing the number of abnormal discharges during sputtering and the amount of pores (voids) in the oxide sintered material.

[3] In the oxide sintered material according to the present embodiment, the content of the In₂(ZnO)ₘO₃ crystal phase is preferably 1 mass % or more and less than 90 mass %, which is advantageous in reducing the number of abnormal discharges during sputtering and the amount of pores in the oxide sintered material.

[4] The oxide sintered material of the present embodiment may further include a ZnWO₄ crystal phase, which is advantageous in reducing the number of abnormal discharges during sputtering and the amount of pores in the oxide sintered material.

[5] When the ZnWO₄ crystal phase is further included in the oxide sintered material according to the present embodiment, the content of the ZnWO₄ crystal phase is preferably 0.1 mass % or more and less than 10 mass %, which is advantageous in reducing the number of abnormal discharges during sputtering and the amount of pores in the oxide sintered material.

[6] In the oxide sintered material according to the present embodiment, the content of W relative to the total content of In, W and Zn in the oxide sintered material is preferably greater than 0.01 atom % and smaller than 20 atom %, which is advantageous in reducing the number of abnormal discharges during sputtering and the amount of pores in the oxide sintered material.

[7] In the oxide sintered material according to the present embodiment, the content of Zn relative to the total content of In, W and Zn in the oxide sintered material is preferably greater than 1.2 atom % and smaller than 60 atom %, which is advantageous in reducing the number of abnormal discharges during sputtering and the amount of pores in the oxide sintered material.

[8] In the oxide sintered material according to the present embodiment, the ratio of the content of Zn relative to the content of W in the oxide sintered material is preferably greater than 1 and smaller than 20000 by atom ratio, which is advantageous in reducing the number of abnormal discharges during sputtering and/or the amount of pores in the oxide sintered material.

[9] The oxide sintered material according to the present embodiment may further contain zirconium (Zr). In this case, the content of Zr relative to the total content of In, W, Zn and Zr in the oxide sintered material is preferably 0.1 ppm or more and 200 ppm or less by atom ratio, which is advantageous in making excellent the characteristics of a semiconductor device including an oxide semiconductor film that is formed by using a sputtering target including the oxide sintered material according to the present embodiment.

[10] A sputtering target according to another embodiment of the present invention includes the oxide sintered material of the above embodiment. Since the sputtering target according to the present embodiment includes the oxide sintered material of the above embodiment, it is possible to reduce the number of abnormal discharges during sputtering. Moreover, since the sputtering target according to the present embodiment is used to form an oxide semiconductor film, it is possible to make excellent the characteristics of the semiconductor device containing such oxide semiconductor film.

[11] The method of manufacturing a semiconductor device according to still another embodiment of the present invention is a method of manufacturing a semiconductor device including an oxide semiconductor film, and the method includes preparing the sputtering target of the above embodiment, and forming the oxide semiconductor film by a sputtering method using the sputtering target. According to the manufacturing method of the present embodiment, since the oxide semiconductor film is formed by the sputtering method using the sputtering target of the above embodiment, it is possible to reduce the number of abnormal discharges during sputtering, and it is possible to make excellent the characteristics of the semiconductor device including the oxide semiconductor film.

The semiconductor device is not particularly limited, and as a preferable example, a TFT (thin film transistor) which includes the oxide semiconductor film as a channel layer may be given.

[12] An oxide semiconductor film according to still another embodiment of the present invention is an oxide semiconductor film containing In, W and Zn. The oxide semiconductor film is amorphous, and the average number of oxygen atoms coordinated to an indium atom is 2 or more and less than 4.5.

According to the present embodiment, it is possible to make excellent the characteristics of the semiconductor device which includes the oxide semiconductor film as a channel layer.

[13] In the oxide semiconductor film according to the present embodiment, the content of W relative to the total content of In, W and Zn in the oxide semiconductor film is preferably greater than 0.01 atom % and smaller than 20 atom %, which is advantageous in making excellent the characteristics of a semiconductor device which includes the oxide semiconductor film as a channel layer.

[14] In the oxide semiconductor film according to the present embodiment, the content of Zn relative to the total content of In, W and Zn in the oxide semiconductor film is preferably greater than 1.2 atom % and smaller than 60 atom %, which is advantageous in making excellent the characteristics of a semiconductor device which includes the oxide semiconductor film as a channel layer.

[15] In the oxide semiconductor film according to the present embodiment, the ratio of the content of Zn relative to the content of W in the oxide semiconductor film is preferably greater than 1 and less than 20000 by atom ratio, which is advantageous in making excellent the characteristics of a semiconductor device which includes the oxide semiconductor film as a channel layer.

[16] The oxide semiconductor film according to the present embodiment may further contain Zr. In this case, the content of Zr relative to the total content of In, W, Zn, and Zr in the oxide semiconductor film is preferably 0.1 ppm or more to 2000 ppm or less by mass, which is advantageous in making excellent the characteristics of a semiconductor device which includes the oxide semiconductor film as a channel layer.

[17] The method of manufacturing an oxide sintered material according to still another embodiment of the present invention is a method of manufacturing an oxide sintered material according to the above embodiment. The method includes forming the oxide sintered material by sintering a molded body containing indium, tungsten and zinc. Forming the oxide sintered material includes placing the molded body for 2 hours or more in an atmosphere having an oxygen concentration greater than that in the air at a first temperature lower than the maximum temperature in forming the oxide sintered material. The first temperature is 300° C. or more and less than 600° C.

According to the manufacturing method mentioned above, it is possible to manufacture efficiently the oxide sintered material of the above embodiment.

### DETAILS OF EMBODIMENTS

### Embodiment 1: Oxide Sintered Material

The oxide sintered material according to the present embodiment contains In, W and Zn as metal elements, includes an In₂O₃ crystal phase and an In₂(ZnO)ₘO₃ crystal phase (m represents a natural number), and the average number of oxygen atoms coordinated to an indium atom is 3 or more and less than 5.5.

According to the oxide sintered material, it is possible to reduce the number of abnormal discharges during sputtering, and it is possible to make excellent the characteristics of a semiconductor device including an oxide semiconductor film that is formed by using a sputtering target including the oxide sintered material.

The excellent characteristics of the semiconductor device include, for example, the reliability of the semiconductor device under light irradiation and the field-effect mobility of the semiconductor device such as a TFT.

(1) In₂O₃ Crystal Phase

In the present specification, the term of “In₂O₃ crystal phase” refers to a crystal of an indium oxide mainly containing In and oxygen (O). More specifically, the In₂O₃ crystal phase is a bixbyite type crystal phase having a crystal structure defined in JCPDS (Joint Committee for Powder Diffraction Standards) card 6-0416, and is also called as rare earth oxide C-type phase (or C-rare earth structure phase). As long as the In₂O₃ crystal phase exhibits the above crystal system, the lattice constant thereof may vary due to the deficiency of oxygen, or the solid-dissolution of or the deficiency of element In and/or element W and/or element Zn or the solid-dissolution of other metal elements.

In the oxide sintered material, the content of the In₂O₃ crystal phase is preferably 10 mass % or more and less than 98 mass %, which is advantageous in reducing the number of abnormal discharges during sputtering and reducing the amount of pores in the oxide sintered material.

The content of the In₂O₃ crystal phase refers to the ratio (mass %) of the In₂O₃ crystal phase when the total amount of the crystal phases determined by X-ray diffraction measurement to be described below is set to 100 mass %. The same applies to the other crystal phases.

When the content of the In₂O₃ crystal phase is 10 mass % or more, it is advantageous in reducing the number of abnormal discharges during sputtering, and when the content of the In₂O₃ crystal phase is less than 98 mass %, it is advantageous in reducing the amount of pores in the oxide sintered material.

In order to reduce the number of abnormal discharges during sputtering and reduce the amount of pores in the oxide sintered material, the content of the In₂O₃ crystal phase is more preferably 25 mass % or more, further preferably 40 mass % or more, and even more preferably 50 mass % or more, and may be 70 mass % or more or 75 mass % or more. In order to reduce the number of abnormal discharges during sputtering and reduce the amount of pores in the oxide sintered material, the content of the In₂O₃ crystal phase is more preferably 95 mass % or less, further preferably 90 mass % or less, even more preferably less than 90 mass %, and particularly preferably less than 80 mass %.

The In₂O₃ crystal phase may be identified by X-ray diffraction measurement. Similarly, the other crystal phases such as the In₂(ZnO)ₘO₃ crystal phase and the ZnWO₄ crystal phase may be identified by X-ray diffraction measurement. In other words, the presence of at least both the In₂O₃ crystal phase and the In₂(ZnO)ₘO₃ crystal in the oxide sintered material according to the present embodiment is confirmed by the X-ray diffraction measurement. Moreover, the X-ray diffraction measurement may be used to determine the lattice constant of the In₂(ZnO)ₘO₃ crystal phase and the plane spacing of the In₂O₃ crystal phase.

The X-ray diffraction measurement may be performed under the following conditions or equivalent conditions.

(Conditions for X-Ray Diffraction Measurement)

θ-2θ method

X-ray source: Cu Kα ray

X-ray tube voltage: 45 kV

X-ray tube current: 40 mA

Step width: 0.02°

Step time: 1 second/step

Measurement range 2θ: 10° to 80°

The content of the In₂O₃ crystal phase may be calculated by the RIR method (Reference Intensity Ratio) using X-ray diffraction. Similarly, the content of other crystal phases such as the In₂(ZnO)ₘO₃ crystal phase and the ZnWO₄ crystal phase may also be calculated by the RIR method using X-ray diffraction.

Generally, the RIR method quantifies the content based on the integral intensity ratio of the strongest line of each crystal phase and the RIR value described in the ICDD card, but in the case of a complex oxide such as the oxide sintered material according to the present embodiment which is difficult to separate the peak of the strongest line, firstly, the X-ray diffraction peaks clearly separated for each compound are selected, and then the content of each crystal phase is calculated from the integrated intensity ratio and the RIR value (or by an equivalent method). The measurement conditions of X-ray diffraction performed in determining the content of each crystal phase are the same as or equivalent to the above-mentioned conditions.

(2) In₂(ZnO)ₘO₃ Crystal Phase In the present specification, the “In₂(ZnO)ₘO₃ crystal phase” is a general term of a crystal phase of a complex oxide crystal which mainly contains In, Zn and O, and has a laminated structure called a homologous structure. As an example of the In₂(ZnO)ₘO₃ crystal phase, a Zn₄In₂O₇ crystal phase may be given. The Zn₄In₂O₇ crystal phase is a crystal phase of a complex oxide of In and Zn which has a crystal structure represented by a space group P63/mmc (194) and a crystal structure defined by JCPDS card 00-020-1438. As long as the In₂(ZnO)ₘO₃ crystal phase exhibits the above crystal system, the lattice constant thereof may vary due to the deficiency of oxygen, or the solid-dissolution of or the deficiency of element In and/or element W and/or element Zn or the solid-dissolution of other metal elements.

In the formula, m represents a natural number (a positive integer), and it is generally a natural number of 1 or more and 10 or less, preferably a natural number of 2 or more and 6 or less, and more preferably a natural number of 3 or more and 5 or less.

According to the oxide sintered material according to the present embodiment containing the In₂O₃ crystal phase and the In₂(ZnO)ₘO₃ crystal phase, it is possible to reduce the number of abnormal discharges during sputtering. The possible reason may be that the electric resistance of the In₂(ZnO)ₘO₃ crystal phase is smaller than that of the In₂O₃ crystal phase.

In the oxide sintered material, the content of the In₂(ZnO)ₘO₃ crystal phase is preferably 1 mass % or more and less than 90 mass %, which is advantageous in reducing the number of abnormal discharges during sputtering and reducing the amount of pores in the oxide sintered material.

When the content of the In₂(ZnO)ₘO₃ crystal phase is 1 mass % or more, it is advantageous in reducing the number of abnormal discharges during sputtering, and when the content of the In₂(ZnO)ₘO₃ crystal phase is less than 90 mass %, it is advantageous in reducing the amount of pores in the oxide sintered material.

In order to reduce the number of abnormal discharges during sputtering and reducing the amount of pores in the oxide sintered material, the content of the In₂(ZnO)ₘO₃ crystal phase is more preferably 5 mass % or more, further preferably 9 mass % or more and even more preferably 21 mass % or more but more preferably 80 mass % or less, and further preferably 70 mass % or less, and may be less than 50 mass %, 30 mass % or less, or 20 mass % or less.

The In₂(ZnO)ₘO₃ crystal phase grows into a spindle shape in the sintering step, and thereby, it is present in the oxide sintered material as spindle-shaped particles. The aggregate of spindle-shaped particles tends to generate more pores in the oxide sintered material than the aggregate of circular particles. Therefore, the content of the In₂(ZnO)ₘO₃ crystal phase is preferably less than 90 mass %. On the other hand, if the content of the In₂(ZnO)ₘO₃ crystal phase is too small, the electrical resistance of the oxide sintered material increases, causing the arcing frequency to increase during sputtering. Thus, the content of the In₂(ZnO)ₘO₃ crystal phase is preferably 1 mass % or more.

As to be described later, in order to reduce the amount of pores in the oxide sintered material, it is preferred that the oxide sintered material further includes a ZnWO₄ crystal phase. If the ZnWO₄ crystal phase is further included, it is possible to fill the space between the spindle-shaped particles composed of the In₂(ZnO)ₘO₃ crystal phase with particles composed of the ZnWO₄ crystal phase, which makes it possible to reduce the amount of pores in the oxide sintered material.

In order to reduce the number of abnormal discharges during sputtering, the total content of the In₂O₃ crystal phase and the Zn₄In₂O₇ crystal phase is preferably 80 mass % or more, and more preferably 85 mass % or more.

(3) ZnWO₄ Crystal Phase

The oxide sintered material may further include a ZnWO₄ crystal phase, which is advantageous in reducing the number of abnormal discharges during sputtering and reducing the amount of pores in the oxide sintered material.

In the present specification, the term of “ZnWO₄ crystal phase” refers to a crystal of a complex oxide mainly containing Zn, W and O. More specifically, the ZnWO₄ crystal phase is a zinc tungstate compound crystal phase having a crystal structure represented by a space group of P12/c1(13) and having a crystal structure defined in JCPDS card 01-088-0251. As long as the ZnWO₄ crystal phase exhibits the above crystal system, the lattice constant thereof may vary due to the deficiency of oxygen, or the solid-dissolution of or the deficiency of element In and/or element W and/or element Zn or the solid-dissolution of other metal elements.

In the oxide sintered material, the content of the ZnWO₄ crystal phase is preferably 0.1 mass % or more and less than 10 mass %, which is advantageous in reducing the number of abnormal discharges during sputtering and reducing the amount of pores in the oxide sintered material. The content of ZnWO₄ crystal phase is more preferably 0.5 mass % or more and further preferably 0.9 mass % or more so as to reduce the amount of pores in the oxide sintered material, and is more preferably 5.0 mass % or less and further preferably 2.0 mass % or less so as to reduce the number of abnormal discharges during sputtering.

The content of the ZnWO₄ crystal phase may be calculated by the above-mentioned RIR method using X-ray diffraction. It is found that the ZnWO₄ crystal phase has a higher electrical resistivity than the In₂O₃ crystal phase and the In₂(ZnO)ₘO₃ crystal phase. Therefore, if the content of the ZnWO₄ crystal phase in the oxide sintered material is too high, the number of abnormal discharges may occur in the ZnWO₄ crystal phase during sputtering. On the other hand, if the content of the ZnWO₄ crystal phase is less than 0.1 mass %, even though the ZnWO₄ crystal phase is included, the gap between the particles composed of the In₂O₃ crystal phase and the particles composed of the In₂(ZnO)ₘO₃ crystal phase may not be sufficiently filled by the particles composed of the ZnWO₄ crystal phase, deteriorating the effect of reducing the amount of pores.

(4) Average Number of Oxygen Atoms Coordinated to Indium Atom

In the oxide sintered material according to the present embodiment, the average number of oxygen atoms coordinated to the indium atom is 3 or more and less than 5.5. Thus, it is possible to reduce the number of abnormal discharges during sputtering, and it is possible to make excellent the characteristics of a semiconductor device including an oxide semiconductor film that is formed by using a sputtering target including the oxide sintered material. The excellent characteristics of the semiconductor device include the reliability of the semiconductor device under light irradiation and the field-effect mobility of the semiconductor device such as a TFT.

The average number of oxygen atoms coordinated to an indium atom refers to the oxygen atoms that are present most closely to the indium atom.

In the case of the In₂O₃ crystal phase or the In₂(ZnO)ₘO₃ crystal phase, for example, the average number of oxygen atoms coordinated to an indium atom is stoichiometrically six.

If the average number of oxygen atoms coordinated to the indium atom is 5.5 or more, the conductivity of a compound composed of In and oxygen (for example, the In₂O₃ crystal phase or the In₂(ZnO)ₘO₃ crystal phase) decreases. As a result, when a sputtering target including the oxide sintered material is used to perform the sputtering, the number of abnormal discharges increases as a DC voltage is applied. Thus, the average number of oxygen atoms coordinated to the indium atom in the oxide sintered material is preferably less than 5, and more preferably less than 4.9.

If the average number of oxygen atoms coordinated to the indium atom in the oxide sintered material is less than 3, the reliability under light irradiation of a semiconductor device including an oxide semiconductor film that is formed by using the sputtering target including the oxide sintered material decreases. Thus, the average number of oxygen atoms coordinated to the indium atom in the oxide sintered material is preferably greater than 3.5, and more preferably greater than 3.8.

It is said that when an oxide semiconductor film contains In₂O₃ as the main component, regardless of whether the film is amorphous or not, oxygen voids or oxygen solid solution may greatly affect the electrical characteristics of the oxide semiconductor film. For example, it is said that an oxygen void may function as a donor site that donates electrons.

If the average number of oxygen atoms coordinated to the indium atom in an oxide sintered material is limited to a predetermined range and a sputtering target including the oxide sintered material is used as a raw material to form the oxide semiconductor film, it is possible to modify the characteristics of the oxide semiconductor film, and as a result, it is possible to make excellent the characteristics of the semiconductor device including the oxide semiconductor film.

When manufacturing an oxide semiconductor film by sputtering a sputtering target including an oxide sintered material in a gas mixture of an inert gas such as argon and an oxygen gas, it is generally considered that the average number of oxygen atoms coordinated to the indium atom in the oxide sintered material which serves as the raw material will not affect the average number of oxygen atoms coordinated to the indium atom in the oxide semiconductor film which is obtained after sputtering, but it was found that actually it does.

For example, the oxygen atoms introduced from the oxygen gas during sputtering and the oxygen atoms preliminarily included in the oxide sintered material are different in bonding state with a metal element (such as In, W or Zn). Specifically, the oxygen atoms introduced into the oxide semiconductor film from the oxygen gas are weakly bonded to the metal element, and most of the oxygen atoms are present as interstitially dissolved oxygen. On the other hand, the oxygen atoms present in the oxide sintered material are strongly bonded to the metal element, which makes it possible to easily form a strong bond with the metal element in the oxide semiconductor film.

The oxygen atoms interstitially dissolved in the oxide semiconductor film tend to decrease the reliability of the semiconductor device (such as TFT) under light irradiation. Therefore, in order to make excellent the characteristics of the semiconductor device including the oxide semiconductor film, it is preferable to increase the average number of oxygen atoms coordinated to the indium atom in the oxide sintered material, so that more oxygen atoms in the oxide semiconductor film are bonded to the metal element (such as In, W or Zn) so as to reduce the number of interstitially dissolved oxygen atoms.

Although the oxygen atoms introduced from the oxygen gas into the oxide semiconductor film may bond to the metal elements in the oxide semiconductor film, most of them will become interstitially dissolved oxygen atoms at the same time. In order to use an oxide semiconductor film as a channel layer in a semiconductor device, an optimal amount of oxygen defects should be present in the oxide semiconductor film. However, when oxygen gas is introduced so as to obtain the optimal amount of oxygen defects, the amount of the oxygen atoms that are interstitially dissolved increases too much, which may lower the reliability under light irradiation of the semiconductor device including the obtained oxide semiconductor film.

The average number of oxygen atoms coordinated to the indium atom may be identified by XAFS (X-ray Absorption Fine Structure) measurement. The XAFS measurement is configured to measure variations on the X-ray absorptivity of a test sample by continuously varying the wavelength (energy) of X-rays incident on the test sample. Since high-energy X-rays are required, SPring-8 BL16B2 was used to perform the measurement.

The XAFS measurement may be performed under the following conditions.

(Conditions of XAFS Measurement)

Device: SPring-8 BL16B2

X-ray: which is monochromatically processed by using Si 111 crystal around In-K edge (27.94 keV), and harmonics thereof are removed by using Rh-coated mirror

Measurement method: transmission method

Preparation of test sample: 28 mg of oxide sintered material powder was mixed with 174 mg of hexagonal boron nitride and molded into tablets

Incident and transmission X-ray detector: ion chamber

Analysis method: only the EXAFS (Extended X-ray Absorption Fine Structure) regions are extracted from the obtained XAFS spectrum and analyzed.

As the software, REX 2000 made by Rigaku Corporation is used. EXAFS oscillations are extracted by using the algorithm of Cook & Sayers, weighted by the cube of the wave number, and subjected to Fourier transformation until k=16 so as to obtain the radial structure function.

The average number of oxygen atoms coordinated to the indium atom is obtained through fitting in the range of 0.08 nm to 0.22 nm of the radial structure function by assuming that the first peak is a kind of In—O bond. As the backscattering intensity and the phase shift, the Mckale theoretical values are used.

(5) Content of Elements

The content of W (hereinafter also referred to as “W content”) relative to the total content of In, W and Zn in the oxide sintered material is preferably greater than 0.1 atom % and smaller than 20 atom %, and the content of Zn (hereinafter also referred to as “Zn content”) relative to the total content of In, W and Zn in the oxide sintered material is preferably greater than 1.2 atom % and smaller than 60 atom %, which is advantageous in reducing abnormal discharge during sputtering and reducing the amount of pores in the oxide sintered material.

In order to reduce the amount of pores in the oxide sintered material, the W content is more preferably 0.02 atom % or more, further preferably 0.03 atom % or more, even more preferably 0.05 atom % or more, and particularly preferably 0.1 atom % or more, and in order to reduce the number of abnormal discharges during sputtering, the W content is more preferably 10 atom % or less, further preferably 5 atom % or less, even more preferably 1.2 atom % or less, and particularly preferably 0.5 atom % or less.

It is preferred that the W content is greater than 0.01 atom % so as to reduce the amount of pores in the oxide sintered material. As described above, the gap between the particle composed of the In₂O₃ crystal phase and the particle composed of the In₂(ZnO)ₘO₃ crystal phase may be filled by the particle composed of the ZnWO₄ crystal phase, which makes it possible to reduce the amount of pores in the oxide sintered material.

Therefore, in order to obtain an oxide sintered material with a small amount of pores, it is preferred that the particles composed of the ZnWO₄ crystal phase are generated with high dispersion during sintering. In the sintering step, if the element Zn and the element W are brought into contact with each other efficiently, the reaction will be promoted, which makes it possible to form the particles composed of the ZnWO₄ crystal phase. Therefore, if the W content in the sintered material is made more than 0.1 atom %, the element Zn and the element W may be brought into contact with each other efficiently.

If the W content is 0.01 atom % or less, switching driving can not be confirmed in a semiconductor device including an oxide semiconductor film that is formed by using an oxide sintered material as a sputtering target. The possible reason may be that the electric resistance of the oxide semiconductor film is too low.

If the W content is 20 atom % or more, the content of the particles composed of the ZnWO₄ crystal phase in the oxide sintered material becomes too large relatively, it is impossible to suppress abnormal discharge starting from the particles composed of the ZnWO₄ crystal phase, which makes it difficult to reduce the number of abnormal discharges during sputtering.

In order to reduce the amount of pores in the oxide sintered material, the Zn content is more preferably 2.0 atom % or more, further preferably 5.0 atom % or more, even more preferably 10.0 atom % or more, particularly preferably more than 10.0 atom %, still preferably more than 20.0 atom %, and most preferably more than 25.0 atom %. On the other hand, in order to reduce the amount of pores in the oxide sintered material, the Zn content is more preferably less than 55 atom %, further preferably less than 50 atom %, even more preferably less than 45 atom %, and particularly preferably 40 atom % or less.

The Zn content is preferably more than 1.2 atom % and less than 60 atom % so as to reduce the amount of pores in the oxide sintered material. If the Zn content is 1.2 atom % or less, it would be difficult to reduce the amount of pores in the oxide sintered material. If the Zn content is 60 atom % or more, the content of the In₂(ZnO)ₘO₃ crystal phase in the oxide sintered material becomes relatively too large, it would be difficult to reduce the amount of pores in the oxide sintered material.

The Zn content has an effect of maintaining a high field-effect mobility for a semiconductor device including an oxide semiconductor film formed by using the oxide sintered material as a sputtering target even if it is annealed at a high temperature. Therefore, the Zn content is more preferably 2.0 atom % or more, further preferably 5.0 atom % or more, still more preferably 10.0 atom % or more, even more preferably more than 10.0 atom %, particularly preferably more than 20.0 atom %, and most preferably more than 25.0 atom %.

The contents of In, Zn and W in the oxide sintered material may be measured by ICP emission spectrometry. The In content means the amount of In/(the amount of In+the amount of Zn+the amount of W) expressed in terms of percentage, the Zn content means the amount of Zn/(the amount of In+the amount of Zn+the amount of W) expressed in terms of percentage, and the W content means the amount of W/(the amount of In+the amount of Zn+the amount of W) expressed in terms of percentage. Each amount is expressed by the number of atoms.

The ratio of the Zn content to the W content in the oxide sintered material (hereinafter also referred to as “Zn/W ratio”) is preferably greater than 1 and less than 20000 by atom ratio, which is advantageous in reducing the amount of pores in the oxide sintered material and/or reducing the number of abnormal discharges during sputtering.

In order to reduce the amount of pores, the Zn/W ratio is more preferably more than 10 and further preferably more than 15 but more preferably less than 2000, further preferably 500 or less, even more preferably less than 410, particularly preferably less than 300, and especially preferably less than 200.

As described above, the particles composed of the ZnWO₄ crystal phase function as an auxiliary agent that promotes sintering in the sintering step by filling the gap between the particles composed of the In₂O₃ crystal phase and the particles composed of the In₂(ZnO)ₘO₃ crystal phase so as to improve the sintering density, which makes it possible to reduce the amount of pores in the oxide sintered material. Therefore, it is preferred that the ZnWO₄ crystal phase is generated with high dispersion during sintering so as to obtain an oxide sintered material with a small amount of pores. In the sintering step, if the element Zn and the element W are brought into contact with each other efficiently, the reaction will be promoted, which makes it possible to form the ZnWO₄ crystal phase efficiently.

In order to form a highly dispersed ZnWO₄ crystal phase during the sintering step, it is preferred that that the element Zn is present at a larger amount than the element W. Therefore, the Zn/W ratio is preferably greater than 1 in this respect. If the Zn/W ratio is 1 or less, the ZnWO₄ crystal phase may not be formed with high dispersion during the sintering step, which makes it difficult to reduce the amount of pores. Furthermore, if the Zn/W ratio is 1 or less, Zn preferentially reacts with W during the sintering step to form the ZnWO₄ crystal phase, so that the amount of Zn for forming the In₂(ZnO)ₘO₃ crystal phase becomes insufficient, and as a result, the In₂(ZnO)ₘO₃ crystal phase is less likely to be formed in the oxide sintered material, and consequently, the electrical resistance of the oxide sintered material increases, causing the arcing frequency to increase during sputtering.

If the Zn/W ratio is 20000 or more, the content of the In₂(ZnO)ₘO₃ crystal phase in the oxide sintered material becomes too large, it would be difficult to reduce the amount of pores in the oxide sintered material.

The oxide sintered material may further contain zirconium (Zr). In this case, the content of Zr (hereinafter also referred to as “Zr content”) relative to the total content of In, W, Zn and Zr in the oxide sintered material is preferably 0.1 ppm or more and 200 ppm or less by atom ratio, which is advantageous in making excellent the characteristics of a semiconductor device including an oxide semiconductor film that is formed by using a sputtering target including the oxide sintered material according to the present embodiment.

Thus, the inclusion of Zr in the oxide sintered material at the content mentioned above is, for example, advantageous in maintaining a high field-effect mobility for the semiconductor device even if the semiconductor device is annealed at a high temperature and maintaining a high reliability of the semiconductor device under light irradiation.

In order to maintain a high field-effect mobility for the semiconductor device even if the semiconductor device is annealed at a high temperature, the Zr content is more preferably 0.5 ppm or more, and further preferably 2 ppm or more. In order to maintain a higher field-effect mobility for the semiconductor device and maintain a higher reliability under light irradiation for the semiconductor device, the Zr content is more preferably less than 100 ppm, and further preferably less than 50 ppm.

The Zr content in the oxide sintered material may be measured by ICP emission spectrometry. The Zr content means the amount of Zr/(the amount of In+the amount of Zn+the amount of W+the amount of Zr), which is expressed in terms of ppm percentage. Each amount is expressed by the number of atoms.

### Embodiment 2: Method of Manufacturing Oxide Sintered Material

In order to efficiently manufacture the oxide sintered material according to Embodiment 1, it is preferred that the method of manufacturing the oxide sintered material includes forming the oxide sintered material by sintering a molded body containing In, W and Zn (sintering step), and that forming the oxide sintered material includes placing the molded body for 2 hours or more in an atmosphere having an oxygen concentration greater than that of the air at a first temperature lower than the maximum temperature in forming the oxide sintered material. The first temperature is preferably 300° C. or more and less than 600° C.

The pressure of the atmosphere for placing the molded body for 2 hours or more is preferably equal to the air pressure.

The relative humidity (at 25° C. in the entire disclosure) of the atmosphere for placing the molded body for 2 hours or more is preferably 40 RH % or more.

It is more preferable that the atmosphere for placing the molded body for 2 hours or more has a pressure equal to the air pressure, an oxygen concentration greater than that in the air, and a relative humidity of 40 RH % or more.

If the oxygen concentration in the atmosphere for placing the molded body for 2 hours or more is equal to or lower than that in the air, the average number of oxygen atoms coordinated to the indium atom in the obtained oxide sintered material may become less than 3. In addition, if the relative humidity of the atmosphere for placing the molded body for 2 hours or more is less than 40 RH %, even though the oxygen concentration is greater than that in the air, the average number of oxygen atoms coordinated to the indium atom is likely to become less than 3. Furthermore, if the first temperature is not in the range of 300° C. or more and less than 600° C., the average number of oxygen atoms coordinated to the indium atom possibly become less than 3. If the pressure of the atmosphere for placing the molded body for 2 hours or more is greater than the air pressure, even though the oxygen concentration of the atmosphere is greater than the oxygen concentration in the air and the relative humidity of the atmosphere is 40 RH % or more, the average number of oxygen atoms coordinated to the indium atom may become 5.5 or more.

It should be noted that the first temperature is not necessarily limited to a specific temperature, it may be a temperature range with a margin. Specifically, if a specific temperature selected from a temperature range of 300° C. or more and less than 600° C. is denoted as T (° C.), the first temperature may be for example T±50° C., preferably T±20° C., more preferably T±10° C., and further preferably T±5° C. as long as it is within the temperature range of 300° C. or more and less than 600° C.

It is preferred that the method of manufacturing an oxide sintered material includes:

a step of forming a calcined powder including a crystal phase of a complex oxide containing two elements selected from the group consisting of In, W and Zn;

a step of forming a molded body from the calcined powder; and

a step of forming the oxide sintered material by sintering the molded body (sintering step).

The crystal phase of the complex oxide contained in the calcined powder is preferably at least one crystal phase selected from the group consisting of In₂(ZnO)ₘO₃ crystal phase (m is a natural number), In₆WO₁₂ crystal phase and ZnWO₄ crystal phase.

The In₂(ZnO)ₘO₃ crystal phase and the ZnWO₄ crystal phase are as explained above. The In₂(ZnO)ₘO₃ crystal phase and the ZnWO₄ crystal phase may be identified by X-ray diffraction measurement. A condition for the X-ray diffraction measurement is as explained above.

The In₆WO₁₂ crystal phase is an indium tungstate compound crystal phase which has a trigonal crystal structure and has a crystal structure defined in JCPDS card 01-074-1410. As long as the In₆WO₁₂ crystal phase exhibits the crystal system mentioned above, the lattice constant thereof may vary due to the deficiency of oxygen and/or the solid-dissolution of other metal elements. It should be noted that the indium tungstate compound crystal phase disclosed in Japanese Patent Laying-Open No. 2004-091265 is an InW₃O₉ crystal phase which has a hexagonal crystal structure and has a crystal structure defined in JCPDS card 33-627, and thereby is different from the In₆WO₁₂ crystal phase in the crystal structure.

The In₆WO₁₂ crystal phase may be identified by X-ray diffraction measurement. A condition for the X-ray diffraction measurement is as explained above.

In addition, the complex oxide constituting the calcined powder may be deficient in oxygen or may be subjected to metal substitution.

According to the method including the step of forming a calcined powder containing the In₂(ZnO)ₘO₃ crystal phase and the step of forming a molded body by molding the calcined powder, in the step of forming the oxide sintered material by sintering the molded body (sintering step), if the element Zn and the element W are brought into contact with each other efficiently, the reaction will be promoted, which makes it possible to form the ZnWO₄ crystal phase efficiently. As described above, it is considered that the ZnWO₄ crystal phase plays the role of an auxiliary agent for promoting sintering. Therefore, if the ZnWO₄ crystal phase is generated with high dispersion during sintering, it is possible to obtain an oxide sintered material with a small amount of pores. In other words, if the sintering is performed simultaneously as the ZnWO₄ crystal phase is being formed, it is possible to obtain an oxide sintered material with a small amount of pores.

Further, according to the method including the step of forming a calcined powder containing the In₂(ZnO)ₘO₃ crystal phase and the step of forming a molded body by molding the calcined powder, the In₂(ZnO)ₘO₃ crystal phase tends to remain in the oxide sintered material even after the sintering step, which makes it possible to obtain an oxide sintered material in which the In₂(ZnO)ₘO₃ crystal phase is highly dispersed. The In₂(ZnO)ₘO₃ crystal phase highly dispersed in the oxide sintered material can advantageously reduce abnormal discharge during sputtering.

According to the method including the step of forming a calcined powder containing the In₆WO₁₂ crystal phase and the step of forming a molded body by molding the calcined powder, in the sintering step, if the element Zn and the element W are brought into contact with each other efficiently, the reaction will be promoted, which makes it possible to form the ZnWO₄ crystal phase efficiently. As described above, it is considered that the ZnWO₄ crystal phase plays the role of an auxiliary agent for promoting sintering. Therefore, if the ZnWO₄ crystal phase is generated with high dispersion during sintering, it is possible to obtain an oxide sintered material with a small amount of pores. In other words, if the sintering is performed simultaneously as the ZnWO₄ crystal phase is being formed, it is possible to obtain an oxide sintered material with a small amount of pores.

According to the method including the step of forming a calcined powder containing the In₆WO₁₂ crystal phase and the step of forming a molded body by molding the calcined powder, it is likely that no In₆WO₁₂ crystal phase may remain in the oxide sintered material obtained after the sintering step.

According to the method including the step of forming a calcined powder containing the ZnWO₄ crystal phase and the step of forming a molded body by molding the calcined powder, in the sintering step, the powder containing the ZnWO₄ crystal phase may act at a low temperature, which makes it possible to obtain a sintered material with a high density at a low temperature, and thereby is preferable.

According to the method of manufacturing an oxide sintered material that includes the step of forming a calcined powder containing at least one crystal phase selected from the group consisting of In₂(ZnO)ₘO₃ crystal phase (m is a natural number), In₆WO₁₂ crystal phase and ZnWO₄ crystal phase and the step of forming a molded body by molding the calcined powder, it is possible to reduce the number of abnormal discharges during sputtering, it is possible to reduce the amount of pores in the obtained oxide sintered material and/or it is possible to improve the reliability under light irradiation of a semiconductor device including an oxide semiconductor film formed by using the oxide sintered material as a sputtering target, which is preferable. Moreover, according to the method of manufacturing the oxide sintered material, it is possible to reduce the number of abnormal discharges during sputtering and the amount of pores in the oxide sintered material obtained even at a relatively low sintering temperature, which is preferable.

The method of manufacturing the oxide sintered material according to the present embodiment is not particularly limited, in order to efficiently form the oxide sintered material of Embodiment 1, it should include for example the following steps:

(1) Step of Preparing Raw Powders

As the raw powders of the oxide sintered material, oxide powders of metal elements constituting the oxide sintered material such as the indium oxide powder (for example, In₂O₃ powder), the tungsten oxide powder (for example, WO₃ powder, WO_{2.72} powder, WO₂ powder), and the zinc oxide powder (for example, ZnO powder) are prepared. If the oxide sintered material contains zirconium, then a zirconium oxide powder (for example, ZrO₂ powder) is also prepared as the raw material.

In order to prevent the inclusion of unintentional metal elements and Si into the oxide sintered material so as to obtain a semiconductor device which includes an oxide semiconductor film formed by using the oxide sintered material as a sputtering target and has stable physical properties, it is preferred that the purity of the raw powders is as high as 99.9 mass % or more.

As the tungsten oxide powder, a powder having a chemical composition in which oxygen is deficient as compared with WO₃ powder such as WO_{2.72} powder and WO₂ powder may be used preferably, which makes it possible to obtain an oxide sintered material capable of reducing the number of abnormal discharges during sputtering and having a reduced number and a semiconductor device which includes an oxide semiconductor film formed by using the oxide sintered material as a sputtering target and capable of maintaining a high field-effect mobility even if it is annealed at a high temperature. From this viewpoint, it is more preferable that at least a part of the tungsten oxide powder is the WO_{2.72} powder.

The median particle size d50 of the tungsten oxide powder is preferably 0.1 μm or more and 4 μm or less, more preferably 0.2 μm or more and 2 μm or less, and further preferably 0.3 μm or more and 1.5 μm or less, which makes it possible to obtain an oxide sintered material with appropriate apparent density and mechanical strength as well as reduced amount of pores. The median particle size d50 may be determined by BET specific surface area measurement.

If the median particle diameter d50 of the tungsten oxide powder is smaller than 0.1 μm, it would be difficult to handle the powder, and it would be difficult to uniformly mix the raw material powders. If the median particle size d50 is greater than 4 μm, it would be difficult to reduce the amount of pores in the oxide sintered material to be obtained.

(2) Step of Preparing a Primary Mixture

(2-1) Step of Preparing a Primary Mixture of Indium Oxide Powder and Zinc Oxide Powder

This step is configured to mix (or pulverize and mix) the indium oxide powder and the zinc oxide powder among the raw material powders mentioned above so as to form a calcined powder containing an In₂(ZnO)ₘO₃ crystal phase. The calcined powder containing the In₂(ZnO)ₘO₃ crystal phase may be obtained by subjecting the primary mixture of indium oxide powder and zinc oxide powder to heat treatment.

The value of the natural number m in the In₂(ZnO)ₘO₃ crystal phase may be controlled by adjusting the mixing ratio of the indium oxide powder and the zinc oxide powder. For example, in order to obtain a calcined powder containing a Zn₄In₂O₇ crystal phase, the In₂O₃ powder serving as the indium oxide powder and the ZnO powder serving as the zinc oxide powder are mixed so that the molar ratio of In₂O₃:ZnO=1:4.

The method of mixing the indium oxide powder and the zinc oxide powder is not particularly limited, and it may be either a dry-type method or a wet-type method. Specifically, the indium oxide powder and the zinc oxide powder may be pulverized and mixed by using a ball mill, a planetary ball mill, a bead mill or the like. If the mixture is obtained by the wet-type pulverizing and mixing method, a drying method such as air drying or spray drying may be used to dry the wet mixture.

(2-2) Step of Preparing a Primary Mixture of Indium Oxide Powder and Tungsten Oxide Powder

This step is configured to mix (or pulverize and mix) the indium oxide powder and the tungsten oxide powder among the raw material powders so as to form a calcined powder containing an In₆WO₁₂ crystal phase. The calcined powder containing the In₆WO₁₂ crystal phase may be obtained by subjecting the primary mixture of the indium oxide powder and the tungsten oxide powder to heat treatment.

In order to obtain a calcined powder containing the In₆WO₁₂ crystal phase, the In₂O₃ powder serving as the indium oxide powder and the tungsten oxide powder (for example, WO₃ powder, WO₂ powder, WO_{2.72} powder) are mixed so that the molar ratio of In₂O₃:tungsten oxide powder=3:1.

If an oxide powder containing at least one crystal phase selected from the group consisting of the WO₂ crystal phase and the WO_{2.72} crystal phase is used as the tungsten oxide powder, the calcined powder containing the In₆WO₁₂ crystal phase is easier to be obtained even though a temperature for the heat treatment is low.

The method of mixing the indium oxide powder and the tungsten oxide powder is not particularly limited, and it may be either a dry-type method or a wet-type method. Specifically, the indium oxide powder and the tungsten oxide powder may be pulverized and mixed by using a ball mill, a planetary ball mill, a bead mill or the like. If the mixture is obtained by the wet-type pulverizing and mixing method, a drying method such as air drying or spray drying may be used to dry the wet mixture.

(2-3) Step of Preparing a Primary Mixture of Zinc Oxide Powder and Tungsten Oxide Powder

This step is configured to mix (or pulverize and mix) the zinc oxide powder and the tungsten oxide powder among the raw material powders so as to form a calcined powder containing a ZnWO₄ crystal phase. The calcined powder containing the ZnWO₄ crystal phase may be obtained by subjecting the primary mixture of the zinc oxide powder and the tungsten oxide powder to heat treatment.

In order to obtain a calcined powder containing the ZnWO₄ crystal phase, the zinc powder and the tungsten oxide powder (for example, WO₃ powder, WO₂ powder, WO_{2.72} powder) are mixed so that the molar ratio of ZnO:tungsten oxide powder=1:1.

If an oxide powder containing at least one crystal phase selected from the group consisting of the WO₂ crystal phase and the WO_{2.72} crystal phase is used as the tungsten oxide powder, the calcined powder containing the ZnWO₄ crystal phase is easier to be obtained even though a temperature for the heat treatment is low.

In this step, it is also possible to obtain a calcined powder containing a Zn₂W₃O₈ crystal phase by mixing the zinc oxide powder and the tungsten oxide powder so that the molar ratio of ZnO:tungsten oxide powder=2:3. However, in order to reduce the number of abnormal discharges during sputtering and reduce the amount of pores in the oxide sintered material and/or improve the reliability under light irradiation of a semiconductor device including an oxide semiconductor film formed by using the oxide sintered material as a sputtering target, it is preferred that the calcined powder contains the ZnWO₄ crystal phase.

The method of mixing the zinc oxide powder and the tungsten oxide powder is not particularly limited, and it may be either a dry-type method or a wet-type method. Specifically, the zinc oxide powder and the tungsten oxide powder may be pulverized and mixed by using a ball mill, a planetary ball mill, a bead mill or the like. If the mixture is obtained by the wet-type pulverizing and mixing method, a drying method such as air drying or spray drying may be used to dry the wet mixture.

(3) Step for Forming a Calcined Powder

(3-1) Step of Forming a Calcined Powder Containing the In₂(ZnO)ₘO₃ Crystal Phase

This step is performed after the step of preparing the primary mixture of the indium oxide powder and the zinc oxide powder described above in (2-1), and is configured to form a calcined powder by subjecting the obtained primary mixture to heat treatment (calcination).

In order to prevent the particle size of the calcined product from becoming too large so as to suppress the increase of the pores in the sintered material, the calcination temperature for the primary mixture is preferably less than 1300° C. In order to obtain a calcined powder containing the In₂(ZnO)ₘO₃ crystal phase, the calcination temperature is preferably 550° C. or more, and more preferably 1200° C. or more. As long as the calcination temperature is high enough to form the In₂(ZnO)ₘO₃ crystal phase, it is preferably as low as possible so as to make the particle size of the calcined powder as small as possible.

The calcination atmosphere may be any atmosphere as long as it contains oxygen, and preferably it is an air atmosphere having an air pressure or a pressure higher than the air pressure, or an oxygen-nitrogen mixture atmosphere containing 25 vol % or more of oxygen having an air pressure or a pressure higher than the air pressure. From the viewpoint of improving productivity, the air atmosphere having an air pressure or a pressure around the air pressure is more preferred.

(3-2) Step of Forming a Calcined Powder Containing the In₆WO₁₂ Crystal Phase

This step is performed after the step of preparing the primary mixture of the indium oxide powder and the tungsten oxide powder described in the above (2-2), and is configured to form a calcined powder by subjecting the obtained primary mixture to heat treatment (calcination).

In order to prevent the particle size of the calcined product from becoming too large so as to suppress the increase of the pores in the sintered material and to prevent the sublimation of tungsten, the calcination temperature for the primary mixture is preferably less than 1200° C. In order to obtain a calcined powder containing the In₆WO₁₂ crystal phase, the calcination temperature is preferably 700° C. or more, more preferably 800° C. or more, and further preferably 950° C. or more. As long as the calcination temperature is high enough to form the In₆WO₁₂ crystal phase, it is preferably as low as possible so as to make the particle size of the calcined powder as small as possible.

The calcination atmosphere may be any atmosphere as long as it contains oxygen, and preferably it is an air atmosphere having an air pressure or a pressure higher than the air pressure, or an oxygen-nitrogen mixed atmosphere containing 25 vol % or more of oxygen having an air pressure or a pressure higher than the air pressure. From the viewpoint of improving productivity, the air atmosphere having an air pressure or a pressure around the air pressure is more preferred.

(3-3) Step of Forming a Calcined Powder Containing the ZnWO₄ Crystal Phase

This step is performed after the step of preparing the primary mixture of the zinc oxide powder and the tungsten oxide powder described above in (2-3), and is configured to form a calcined powder by subjecting the obtained primary mixture to heat treatment (calcination).

In order to prevent the particle size of the calcined product from becoming too large so as to suppress the increase of the pores in the sintered material and in order to prevent the sublimation of tungsten, the calcination temperature for the primary mixture is preferably less than 1200° C., more preferably less than 1000° C., and further preferably 900° C. or less. In order to obtain a calcined powder containing the ZnWO₄ crystal phase, the calcination temperature is preferably 550° C. or more. As long as the calcination temperature is high enough to form the ZnWO₄ crystal phase, it is preferably as low as possible so as to make the particle size of the calcined powder as small as possible.

The calcination atmosphere may be any atmosphere as long as it contains oxygen, and preferably it is an air atmosphere having an air pressure or a pressure higher than the air pressure, or an oxygen-nitrogen mixed atmosphere containing 25 vol % or more of oxygen having an air pressure or a pressure higher than the air pressure. From the viewpoint of improving productivity, an air atmosphere having the air pressure or a pressure around the air pressure is more preferred.

(4) Step of Preparing a Secondary Mixture of the Raw Powders Including the Calcined Powder

Similar to the preparation of the primary mixture, in this step, the calcined powder containing the In₂(ZnO)ₘO₃ crystal phase, or the calcined powder containing the In₆WO₁₂ crystal phase, or the calcined powder containing the ZnWO₄ crystal phase (or the Zn₂W₃O₈ crystal phase) is mixed (or pulverized and mixed) with at least one oxide powder selected from the group consisting of the indium oxide powder (for example, the In₂O₃ powder), the tungsten oxide powder (for example, the WO_{2.72} powder), and the zinc oxide powder (for example, the ZnO powder).

Two or more kinds of the calcined powders may be used.

All of the three kinds of the oxide powders mentioned above may be used, it is possible to use only one kind or two kinds. For example, if the calcined powder containing the Zn₂W₃O₈ crystal phase, or the calcined powder containing the ZnWO₄ crystal phase, or the calcined powder containing the In₆WO₁₂ crystal phase is used in the preparation of a secondary mixture, the tungsten oxide powder may not be used. If the calcined powder containing the In₂(ZnO)ₘO₃ crystal phase is used in the preparation of a secondary mixture, the zinc oxide powder may not be used.

If it is desirable for the oxide sintered material to contain zirconium, the zirconium oxide powder (for example, the ZrO₂ powder) may be mixed (or pulverized and mixed) at the same time.

In the preparation of the secondary mixture, it is preferred to adjust the mixing ratio of the raw powders so that the W content, Zn content, Zn/W ratio and the Zr content in the finally obtained oxide sintered material fall within the above-mentioned preferable ranges, respectively.

The method of mixing the oxide powders is not particularly limited, and it may be either a dry-type method or a wet-type method. Specifically, the oxide powders may be pulverized and mixed by using a ball mill, a planetary ball mill, a bead mill or the like. If the mixture is obtained by the wet-type pulverizing and mixing method, a drying method such as air drying or spray drying may be used to dry the wet mixture.

(5) Step of Forming a Molded Body by Molding a Secondary Mixture

Next, the obtained secondary mixture is molded so as to form a molded body containing In, W and Zn. The method of molding the secondary mixture is not particularly limited, but from the viewpoint of improving the apparent density of the oxide sintered material, a uniaxial pressing method, a CIP (Cold Isostatic Pressing) method, a casting method or the like is preferred.

(6) Step of Forming an Oxide Sintered Material by Sintering the Molded Body (Sintering Step)

Next, the obtained molded body is sintered to form an oxide sintered material. At this time, if a hot-press sintering method is used, it would be difficult for the average number of oxygen atoms coordinated to the indium atom to be 3 or more and less than 5.5.

In order to reduce the number of abnormal discharges during sputtering and to obtain an oxide sintered material with a reduced amount of pores, the sintering temperature of the molded body (hereinafter also referred to as “second temperature”) is preferably 800° C. or more and less than 1200° C., more preferably 900° C. or more and further preferably 1100° C. or more, and more preferably 1195° C. or less, and further preferably 1190° C. or less.

If the second temperature is 800° C. or more, it is advantageous in reducing the amount of pores in the oxide sintered material, and if the second temperature is less than 1200° C., it is advantageous in suppressing the deformation of the oxide sintered material so as to fit it properly to the sputtering target.

The maximum temperature in the step of forming the oxide sintered material is in the temperature range of the second temperature.

In order to reduce the number of abnormal discharges during sputtering and obtain an oxide sintered material with reduced amount of pores, it is preferred that the sintering atmosphere is an air-containing atmosphere which has a pressure equal to the air pressure or around the air pressure or has an oxygen concentration greater than that of the air.

As described above, from the viewpoint of efficiently manufacturing the oxide sintered material according to Embodiment 1, the step of forming the oxide sintered material (sintering step) includes a step of placing the molded body for 2 hours or more in an atmosphere having an oxygen concentration greater than that of the air at a first temperature (300° C. or more and less than 600° C.) lower than the maximum temperature in the step of forming the oxide sintered material.

The step of placing the molded body for 2 hours or more at the first temperature is preferably performed after the step of placing the molded body at the second temperature of 800° C. or more and less than 1200° C. In this case, the step of placing the molded body for 2 hours or more at the first temperature can be a cooling process in the sintering step.

More specific conditions or the like for the step of placing the molded body for 2 hours or more at the first temperature have been described in the above.

It is known that W may inhibit the sintering of indium oxide, and consequently increase the amount of pores in the oxide sintered material. However, in the method of manufacturing the oxide sintered material according to the present embodiment, since the calcined powder containing the In₂(ZnO)ₘO₃ crystal phase, the calcined powder containing the In₆WO₁₂ crystal phase, and/or the calcined powder containing the ZnWO₄ crystal phase (or the Zn₂W₃O₈ crystal phase) is used, it is possible to reduce the amount of pores in the oxide sintered material even though the sintering temperature is relatively low.

In order to reduce the number of abnormal discharges during sputtering and to obtain an oxide sintered material with a reduced amount of pores, it is effective that a complex oxide containing Zn having a low melting point and W (such as a complex oxide containing ZnWO₄ crystal phase) is present in the oxide sintered material containing In, W and Zn at the time of sintering. To this end, it is preferable to increase the number of contact points between Zn element and W element at the time of sintering so as to form a complex oxide containing Zn and W in the molded body in a highly dispersed state. Further, since the complex oxide containing Zn and W is formed during the sintering step, it is possible to reduce the number of abnormal discharges during sputtering and to obtain an oxide sintered material with a reduced amount of pores at a low sintering temperature.

Therefore, according to the method that uses a complex oxide containing Zn and In (a complex oxide containing In₂(ZnO)ₘO₃ crystal phase) or a complex oxide containing W and In (a complex oxide of In₆WO₁₂ crystal phase) which has been synthesized in advance in the manufacturing process, the Zn and W elements are highly dispersed so as to increase the number of contact points between the Zn and W elements, which makes it possible to form a complex oxide containing Zn and W at a lower sintering temperature during the sintering step. Thus, it is advantageous in reducing the number of abnormal discharges during sputtering and reducing the amount of pores in the oxide sintered material.

Further, according to the method including the step of forming a calcined powder containing the In₂(ZnO)ₘO₃ crystal phase and the step of forming a molded body by molding the calcined powder, the In₂(ZnO)ₘO₃ crystal phase tends to remain in the oxide sintered material even after the sintering step, which makes it possible to obtain an oxide sintered material in which the In₂(ZnO)ₘO₃ crystal phase is highly dispersed. Alternatively, the highly dispersed In₂(ZnO)ₘO₃ crystal phase may be generated by placing the molded body at the first temperature for 2 hours or more. The In₂(ZnO)ₘO₃ crystal phase highly dispersed in the oxide sintered material is advantageous in reducing the number of abnormal discharges during sputtering.

### Embodiment 3: Sputtering Target

The sputtering target according to the present embodiment includes the oxide sintered material according to Embodiment 1. Therefore, according to the sputtering target of the present embodiment, it is possible to reduce the number of abnormal discharges during sputtering. Moreover, according to the sputtering target of the present embodiment, the characteristics of the semiconductor device including the oxide semiconductor film formed by using the sputtering target may be made excellent. For example, it is possible to provide a semiconductor device capable of maintaining a high field-effect mobility even if it is annealed at a high temperature.

The sputtering target is used as a raw material in the sputtering method. The sputtering method is such a method in which a sputtering target and a substrate are disposed facing each other in a film deposition chamber, a voltage is applied to the sputtering target, which causes rare gas ions to sputter against the surface of the target so as to knock out atoms constituting the target from the target, and the atoms are deposited on the substrate to form a film composed of the atoms constituting the target.

In the sputtering method, the voltage applied to the sputtering target may be a direct current voltage. In this case, it is desired that the sputtering target is conductive. If the sputtering target has a high electric resistance, it is impossible to apply the direct voltage, which makes it impossible to perform the film formation (the formation of an oxide semiconductor film) by the sputtering method. For an oxide sintered material used as a sputtering target, if a partial region thereof has a high electric resistance and the region is wide, since no direct current voltage is applied to the region having a high electric resistance, resulting in a problem such as that the region may not be sputtered appropriately. In other words, abnormal discharge called arcing may occur in the region with a high electric resistance, resulting in a problem such as that the film may not be formed successfully.

The pores in the oxide sintered material are vacancies, each of which contains gas such as nitrogen, oxygen, carbon dioxide, moisture or the like. When such oxide sintered material is used as a sputtering target, the gas is released from the pores in the oxide sintered material, which degrades the degree of vacuum of the sputtering apparatus, and consequently deteriorates the characteristics of the obtained oxide semiconductor film or alternatively causes abnormal discharge to occur from the edge of the pore. Therefore, it is preferred to use an oxide sintered material with a small amount of pores as the sputtering target.

In order to be suitably used in a sputtering method so as to form an oxide semiconductor film of a semiconductor device having excellent characteristics, the sputtering target according to the present embodiment preferably includes the oxide sintered material of Embodiment 1, and more preferably it is made of the oxide sintered material of Embodiment 1.

### Embodiment 4: Oxide Semiconductor Film

The oxide semiconductor film of the present embodiment contains In, W and Zn as metal elements and is amorphous, and the average number of oxygen atoms coordinated to the indium atom is 2 or more and less than 4.5.

According to the oxide semiconductor film, it is possible to make excellent the characteristics of a semiconductor device (for example, a TFT) if it contains the oxide semiconductor film as a channel layer.

The excellent characteristics of the semiconductor device include, for example, the reliability of the semiconductor device under light irradiation and the field-effect mobility of the semiconductor device such as a TFT. For example, according to the oxide semiconductor film mentioned above, even if a semiconductor device including the oxide semiconductor film as a channel layer is annealed at a high temperature, the field-effect mobility of the semiconductor device may be kept high and the reliability thereof under light irradiation may be improved.

(1) Average Number of Oxygen Atoms Coordinated to Indium Atom

In the oxide semiconductor film according to the present embodiment, the average number of oxygen atoms coordinated to an indium atom is 2 or more and less than 4.5.

The average number of oxygen atoms coordinated to an indium atom refers to the oxygen atoms that are present most closely to the indium atom.

If the average number of oxygen atoms coordinated to the indium atom in the oxide semiconductor film is smaller than 2, it would be difficult for the semiconductor device that includes the oxide semiconductor film as a channel layer to have sufficient reliability under light irradiation. If the average number of oxygen atoms coordinated to the indium atom in the oxide semiconductor film is 4.5 or more, it would be difficult for a thin film transistor that includes the oxide semiconductor film as a channel layer to have sufficient field-effect mobility.

From the viewpoint of improving the reliability under light irradiation, the average number of oxygen atoms coordinated to the indium atom in the oxide semiconductor film is preferably more than 2.2. From the viewpoint of maintaining a high field-effect mobility even if it is annealed at a higher temperature, the average number of oxygen atoms coordinated to the indium atom in the oxide semiconductor film is preferably less than 4.2, and more preferably less than 4.0.

When more oxygen atoms contained in the oxide semiconductor film are bonded to a metal (In, W, Zn or the like), the reliability of the semiconductor device under light irradiation tends to increase. However, if oxygen atoms contained in the oxide semiconductor film are present as interstitially dissolved atoms, the reliability of the semiconductor device under light irradiation tends to decrease.

When more oxygen atoms contained in the oxide semiconductor film are bonded to a metal (In, W, Zn or the like), it means that the average number of oxygen atoms coordinated to the indium atom is larger. Therefore, in order to increase the reliability of the semiconductor device under light irradiation, it is preferred to increase the average number of oxygen atoms coordinated to the indium atom in the oxide semiconductor film.

In order to obtain an oxide semiconductor film in which the average number of oxygen atoms coordinated to the indium atom is 2 or more and less than 4.5, it is preferable to use the oxide sintered material of Embodiment 1 as the raw material.

The oxide semiconductor film may be formed by sputtering a sputtering target including the oxide sintered material in a gas mixture of an oxygen gas and an inert gas such as argon. The oxygen atoms introduced from the oxygen gas during sputtering and the oxygen atoms preliminarily included in the oxide sintered material are different in bonding state with a metal element (such as In, W or Zn). Specifically, the oxygen atoms introduced into the oxide semiconductor film from the oxygen gas are weakly bonded to the metal element, and most of the oxygen atoms are present as interstitially dissolved oxygen. Since the interstitially dissolved oxygen is present in a position different from a position most closely to the In atom, it does not become an oxygen atom coordinated to the In atom. On the other hand, the oxygen atoms present in the oxide sintered material are strongly bonded to the metal element, which makes it possible to easily form a strong bond with the metal element in the oxide semiconductor film. Since the oxygen bonded to In is present most closely to the In atom, it becomes an oxygen atom coordinated to the In atom.

The oxygen atoms interstitially dissolved in the oxide semiconductor film tend to decrease the reliability of the semiconductor device (such as TFT) under light irradiation. Therefore, in order to make excellent the characteristics of the semiconductor device including the oxide semiconductor film, it is preferable to increase the average number of oxygen atoms coordinated to the indium atom in the oxide sintered material, so that more oxygen atoms in the oxide semiconductor film are bonded to the metal element (such as In, W or Zn) so as to increase the average number of oxygen atoms coordinated to an indium atom in the oxide semiconductor film and consequently reduce the number of interstitially dissolved oxygen atoms.

Although the oxygen atoms introduced from the oxygen gas into the oxide semiconductor film may bond to the metal elements in the oxide semiconductor film, most of them will become interstitially dissolved oxygen atoms at the same time. In order to use an oxide semiconductor film as a channel layer in a semiconductor device, an optimal amount of oxygen defects should be present in the oxide semiconductor film. However, if the oxygen gas is introduced so as to obtain the optimal amount of oxygen defects, the amount of the oxygen atoms that are interstitially dissolved increases too much, which may lower the reliability under light irradiation of the semiconductor device including the obtained oxide semiconductor film.

Therefore, in order to obtain an oxide semiconductor film in which the average number of oxygen atoms coordinated to the indium atom is 2 or more and less than 4.5, it is preferable to use the oxide sintered material of Embodiment 1 as the raw material.

On the other hand, with regard to the field-effect mobility of a semiconductor device (TFT or the like), it is known that the carrier concentration will increase as the number of oxygen defects increases, and as a result, the field-effect mobility will increase. However, if the average number of oxygen atoms coordinated to the indium atom is larger than 4.5, the number of oxygen defects is too small, the field-effect mobility of the oxide semiconductor film may be about 10 cm²/Vs, which is equivalent to that of In—Ga—Zn—O (In:Ga:Zn=1:1:1). Therefore, from the viewpoint of increasing the field-effect mobility, the average number of oxygen atoms coordinated to the indium atom is preferably less than 4.2, and more preferably less than 4.0.

The average number of oxygen atoms coordinated to the indium atom in the oxide semiconductor film may be identified by XAFS measurement as the oxide sintered material.

The XAFS measurement may be performed under the following conditions.

(Conditions of XAFS Measurement)

Device: SPring-8 BL16B2

X-ray: which is monochromatically processed by using Si 111 crystal around In—K edge (27.94 keV), and harmonics thereof are removed by using Rh-coated mirror, and is incident on the test sample at an angle of 5°

Measurement method: fluorescence method

Test sample: oxide semiconductor film deposited on a glass substrate to the thickness of 50 nm

Incident X-ray detector: ion chamber

Fluorescent X-ray detector: 19-element Ge semiconductor detector

Analysis method: only the EXAFS regions are extracted from the obtained

XAFS spectrum and analyzed.

As the software, REX 2000 made by Rigaku Corporation is used. EXAFS oscillations are extracted by using the algorithm of Cook & Sayers, weighted by the cube of the wave number, and subjected to Fourier transformation until k=10 Å⁻¹ so as to obtain the radial structure function.

The average number of oxygen atoms coordinated to the indium atom is obtained through fitting in the range of 0.08 nm to 0.22 nm of the radial structure function by assuming that the first peak is a kind of In—O bond. As the backscattering intensity and the phase shift, the Mckale theoretical values are used.

(2) Content of Elements

The content of W (hereinafter also referred to as “W content”) relative to the total content of In, W and Zn in the oxide semiconductor film is preferably more than 0.1 atom % and less than 20 atom %, and the content of Zn (hereinafter also referred to as “Zn content”) relative to the total content of In, W and Zn in the oxide semiconductor film is preferably more than 1.2 atom % and less than 60 atom %, which is advantageous in making excellent the characteristics of a semiconductor device which includes the oxide semiconductor film as a channel layer.

In order to further improve the reliability of the semiconductor device under light irradiation, the W content is more preferably more than 0.01 atom % and 8.0 atom % or less.

In order to maintain the high field-effect mobility of the semiconductor device even if it is annealed at a high temperature and further improve the reliability of the semiconductor device under light irradiation, the W content is further preferably 0.02 atom % or more, still further preferably 0.03 atom % or more and particularly preferably 0.05 atom % or more, and further preferably 5.0 atom % or less, still further preferably 1.2 atom % or less and particularly preferably 0.5 atom % or less.

If the W content is 0.01 atom % or less, the reliability of the semiconductor device under light irradiation tends to decrease. if the W content is 20 atom % or more, the field-effect mobility of the semiconductor device tends to decrease.

If the Zn content is 1.2 atom % or less, the reliability of the semiconductor device under light irradiation tends to decrease. If the Zn content is 60 atom % or more, the field-effect mobility of the semiconductor device tends to decrease.

In order to maintain the high field-effect mobility of the semiconductor device even if it is annealed at a high temperature and further improve the reliability of the semiconductor device under light irradiation, the Zn content is more preferably 2.0 atom % or more, further preferably 5.0 atom % or more, still further preferably 10.0 atom % or more, particularly preferably more than 20.0 atom %, and most preferably more than 25.0 atom %.

In order to maintain the high field-effect mobility of the semiconductor device even if it is annealed at a high temperature and further improve the reliability of the semiconductor device under light irradiation, the Zn content is more preferably less than 55 atom %, further preferably less than 50 atom %, and still further preferably 40 atom % or less.

The ratio of the Zn content to the W content in the oxide semiconductor film (hereinafter also referred to as “Zn/W ratio”) is preferably greater than 1 and smaller than 20000 by atom ratio, which is advantageous in making excellent the characteristics of a semiconductor device which includes the oxide semiconductor film as a channel layer.

If the Zn/W ratio in the oxide semiconductor film is 1 or less or 20000 or more, the reliability of the semiconductor device under light irradiation tends to decrease. The Zn/W ratio in the oxide semiconductor film is more preferably 3 or more and further preferably 5 or more but more preferably 2000 or less, further preferably 500 or less, still further preferably 410 or less, particularly preferably 300 or less, and especially preferably 200 or less.

The W content, the Zn content, the Zn/W ratio, and the In/(In+Zn) ratio in the oxide semiconductor film may be determined by RBS (Rutherford backscattering analysis) measurement. The W content may be calculated as the amount of W/(the amount of In+the amount of Zn+the amount of W)×100 based on the amount of In, the amount of Zn, and the amount of W obtained by RBS measurement.

The Zn content may be calculated as the amount of Zn/(the amount of In+the amount of Zn+the amount of W)×100.

The W content and the Zn content are calculated as the percentage by atom ratio. The Zn/W ratio may be calculated as the amount of Zn/the amount of W.

The In/(In+Zn) ratio may be calculated as the amount of In/(the amount of In+the amount of Zn).

The oxide semiconductor film may further include zirconium (Zr). In this case, the content of Zr (hereinafter also referred to as “Zr content”) relative to the total content of In, W, Zn and Zr in the oxide semiconductor film is preferably 0.1 ppm or more and 2000 ppm or less, which is advantageous in making excellent the characteristics of a semiconductor device which includes the oxide semiconductor film as a channel layer.

Generally, Zr is applied to an oxide semiconductor layer for the purpose of improving the chemical resistance or reducing the S value and the OFF current. However, the inventors of the present invention have newly found that if Zr is used in combination with W and Zn in the oxide semiconductor film according to the present embodiment, even if a semiconductor device which includes the oxide semiconductor film as a channel layer is annealed at a high temperature, the field-effect mobility and the reliability thereof under light irradiation may be maintained higher.

If the Zr content is less than 0.1 ppm, the effect that the field-effect mobility of the semiconductor device when it is annealed at a high temperature is maintained higher tends to be insufficient, or the effect that the reliability thereof under light irradiation is maintained higher tends to be insufficient.

If the Zr content is 2000 ppm or less, the effect that the field-effect mobility of the semiconductor device is maintained higher when it is annealed at a high temperature, and the effect that the reliability thereof under light irradiation is maintained higher are easier to be obtained. For the same reason, the Zr content is more preferably 50 ppm or more and 1000 ppm or less.

The Zr content in the oxide semiconductor film may be measured by using ICP-MS (ICP mass spectrometer). In the measurement, an oxide semiconductor film that is completely dissolved in an acid solution is used as a test sample. The Zr content obtained by the measurement method is the amount Zr/(the amount of In+the amount of Zn+the amount of W+the amount of Zr) in terms of mass (mass ratio).

Note that the content of unavoidable metals other than In, W, Zn and Zr relative to the total content of In, W and Zn in the oxide semiconductor film is preferably 1 mass % or less.

(3) Crystallinity of Oxide Semiconductor Film

The oxide semiconductor film according to the present embodiment is amorphous.

In the present specification, when the oxide semiconductor film is “amorphous”, it satisfies the following conditions [i] and [ii]:

[i] no peak resulted from crystals is observed but only a broad peak called “halo” that appears at the low angle side is observed when an X-ray diffraction measurement is performed under the following conditions; and

[ii] a ring-like pattern or an obscure pattern called “halo” is observed when a transmission electron beam diffraction measurement is performed on a minute region by using a transmission electron microscope in accordance with the following conditions.

The ring-like pattern includes the case where spots are clustered to form the ring-like pattern.

(Conditions for X-Ray Diffraction Measurement)

Measurement method: In-plane method (slit collimation method)

X-ray generator: anticathode Cu, output of 50 kV, 300 mA

Detector: scintillation counter

Light Incident unit: slit collimation

Solar slit: a longitudinal divergence angle of 0.48° at the incident side, a longitudinal divergence angle of 0.41° at the light reception side

Slit: S1=1 mm×10 mm at the incident side, S2=0.2 mm×10 mm at the light reception side

Scanning condition: scanning axis of 2θχ/ϕ

Scanning mode: step measurement, scanning range of 10 to 80°, step width of 0.1°, step time of 8 sec.

(Conditions for Transmission Electron Diffraction Measurement)

Measurement method: microscopic electron beam diffraction method

Accelerating voltage: 200 kV

Beam diameter: same as or equivalent to the film thickness of the oxide semiconductor film to be measured

In the oxide semiconductor film according to the present embodiment, a spot-like pattern is not observed by the transmission electron diffraction measurement. In contrast, the oxide semiconductor film disclosed in, for example, Japanese Patent No. 5172918 includes crystals oriented along c-axis in the direction perpendicular to the surface of the layer, and when the nanocrystals are oriented along a certain direction in a minute region as described above, the spot-like pattern is observed. When the oxide semiconductor film according to the present embodiment is observed at least along a plane (the film's cross section) perpendicular to the film surface, the crystals are not oriented with respect to the film surface, and have random orientation. In other words, the crystal axis is not oriented in the thickness direction of the film.

In order to improve the field-effect mobility of the semiconductor device, the oxide semiconductor film is more preferably made of an oxide in which an obscure pattern called “halo” is observed by the transmission electron diffraction measurement. For example, if the Zn content is greater than 10 atom %, the W content is 0.1 atom % or more and the Zr content is 0.1 ppm or more in the oxide semiconductor film, an obscure pattern called “halo” is likely to be observed in the oxide semiconductor film by the transmission electron diffraction measurement. Thus, even if the semiconductor device is annealed at a higher temperature, it is amorphous and stable, which makes it possible to improve the field-effect mobility.

### Embodiment 5: Semiconductor Device and Method of Manufacturing the Same

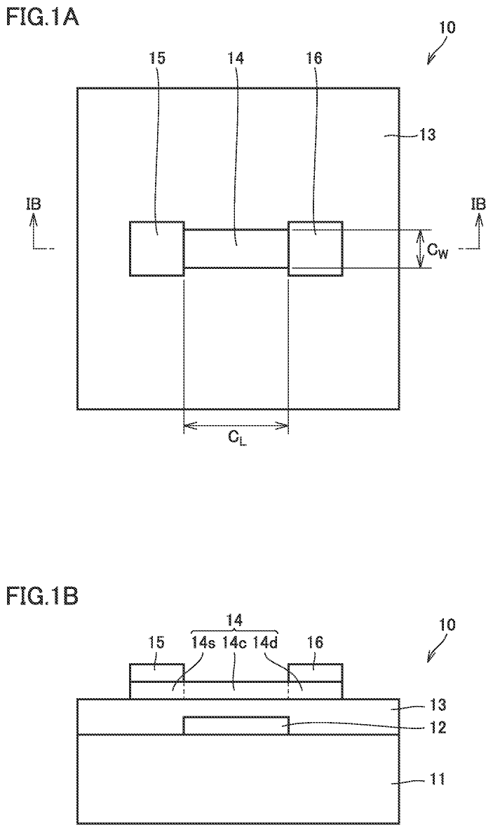

With reference to FIGS. 1A and 1B, a semiconductor device 10 according to the present embodiment includes an oxide semiconductor film 14 formed according to a sputtering method by using a sputtering target of Embodiment 3. Since the semiconductor device according to the present embodiment includes the oxide semiconductor film 14, it can have excellent characteristics.

The excellent characteristics of the semiconductor device include, for example, the reliability of the semiconductor device under light irradiation and the field-effect mobility of the semiconductor device such as a TFT. For example, the semiconductor device according to the present embodiment may have a high field-effect mobility even if it is annealed at a high temperature.

The semiconductor device 10 according to the present embodiment is not particularly limited, but preferably it is a TFT (thin film transistor) because it can maintain a high field-effect mobility even if it is annealed at a high temperature, for example. The oxide semiconductor film 14 included in the TFT is preferably used as a channel layer because the field-effect mobility may be maintained high even when annealed at a high temperature.

Preferably, the oxide semiconductor film 14 in the semiconductor device according to the present embodiment has an electrical resistivity of 10⁻¹ Ωcm or more. Many transparent conductive films containing indium oxide have been investigated so far. In the application of the transparent conductive film, it is required that the electrical resistivity is smaller than 10⁻¹ Ωcm. On the other hand, since the oxide semiconductor film 14 included in the semiconductor device of the present embodiment preferably has an electrical resistivity of 10⁻¹ Ωcm or more, it may be suitably used as a channel layer of a semiconductor device. If a film has an electrical resistivity smaller than 10⁻¹ Ωcm, it is difficult for it to be used as a channel layer of a semiconductor device.

The oxide semiconductor film 14 may be obtained by a manufacturing method including a step of forming a film according to the sputtering method. The sputtering method has been described in the above.

A magnetron sputtering method, a facing target magnetron sputtering method or the like may be used as the sputtering method. As the atmosphere gas for the sputtering, Ar gas, Kr gas or Xe gas may be used, and oxygen may be mixed with these gases.

Further, it is preferable that the oxide semiconductor film 14 is subjected to a heat treatment (annealing) after the film formation by the sputtering method. The oxide semiconductor film 14 obtained by this method is advantageous since it is possible for a semiconductor device (for example, a TFT) including the oxide semiconductor film as a channel layer to maintain the field-effect mobility high even if it is annealed at a high temperature.

The heat treatment after the film formation by the sputtering method may be performed by heating the semiconductor device. In order to obtain excellent characteristics when it is used as a semiconductor device, it is preferable to perform the heat treatment. The heat treatment may be performed immediately after forming the oxide semiconductor film 14 or after forming a source electrode, a drain electrode, an etch stopper layer (ES layer), a passivation film and the like. In order to obtain excellent characteristics when it is used as a semiconductor device, it is more preferable to perform the heat treatment after the etch stopper layer is formed.

If the heat treatment is performed after forming the oxide semiconductor film 14, the substrate temperature is preferably 100° C. or more and 500° C. or less. The atmosphere for the heat treatment may be any atmosphere such as air atmosphere, nitrogen gas, nitrogen gas-oxygen gas, Ar gas, Ar-oxygen gas, water vapor-containing atmosphere, water vapor-containing nitrogen or the like. The pressure of the atmosphere may be air pressure, under a depressurized condition (for example, less than 0.1 Pa from normal pressure), or under a pressurized condition (for example, 0.1 Pa to 9 MPa over normal pressure), but it is preferably air pressure. The time for the heat treatment may be, for example, about 3 minutes to 2 hours, and preferably about 10 minutes to 90 minutes.

In order to obtain higher characteristics (for example, the reliability under light irradiation) when it is used as a semiconductor device, it is desirable that the heat treatment is performed at a higher temperature. However, if the temperature for the heat treatment is raised, the field-effect mobility of the In—Ga—Zn—O-based oxide semiconductor film may be deteriorated. However, if a semiconductor device (for example, a TFT) includes, as a channel layer, the oxide semiconductor film 14 obtained by the sputtering method using the oxide sintered material according to Embodiment 1 as a sputtering target, it is possible for the semiconductor device to maintain a high field-effect mobility even if it is annealed at a high temperature, which is advantageous.

FIGS. 1A, 1B, 2 and 3 are schematic diagrams illustrating some examples of a semiconductor device (TFT) according to the present embodiment. The semiconductor device 10 illustrated in FIGS. 1A and 1B includes a substrate 11, a gate electrode 12 disposed on the substrate 11, a gate insulating film 13 disposed as an insulating layer on the gate electrode 12, a gate insulating film 13, the oxide semiconductor film 14 disposed as a channel layer on the gate insulating film 13, and a source electrode 15 and a drain electrode 16 disposed on the oxide semiconductor film 14 without contacting each other.

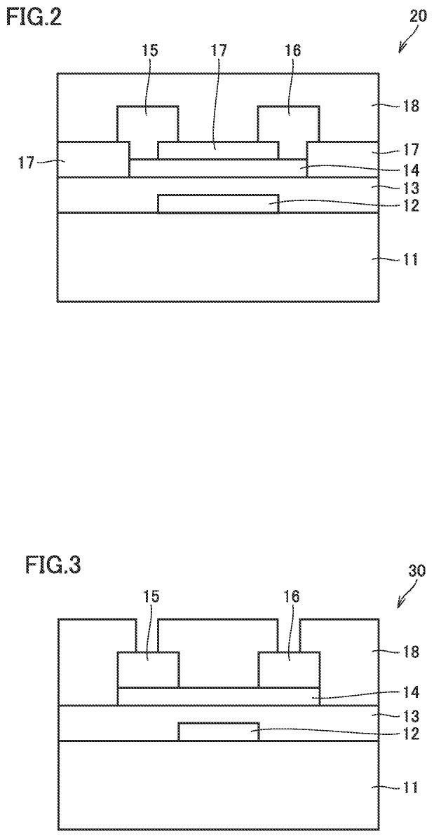

A semiconductor device 20 illustrated in FIG. 2 is the same as the semiconductor device 10 illustrated in FIGS. 1A and 1B except that it further includes an etch stopper layer 17 which is disposed on the gate insulating film 13 and the oxide semiconductor film 14 and is provided with a contact hole, and a passivation film 18 which is disposed on the etch stopper layer 17, the source electrode 15 and the drain electrode 16. Similar to the semiconductor device 10 illustrated in FIGS. 1A and 1B, the passivation film 18 may not be disposed in the semiconductor device 20 illustrated in FIG. 2.

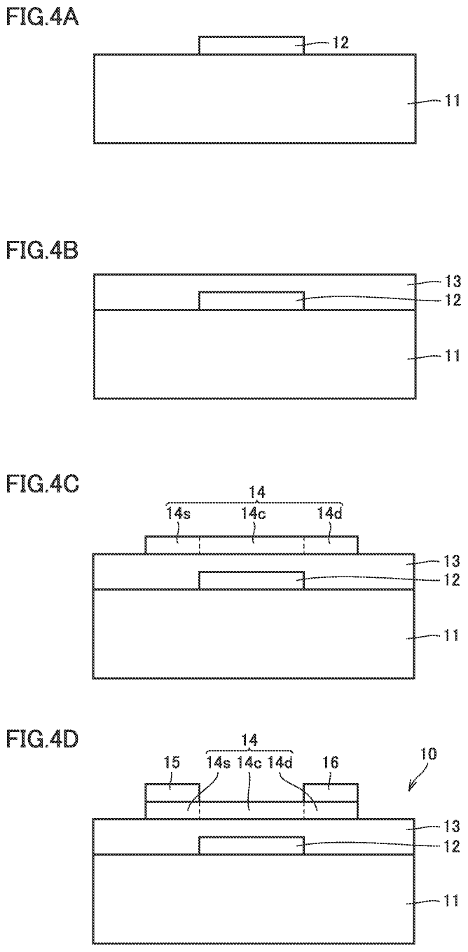

A semiconductor device 30 illustrated in FIG. 3 is the same as the semiconductor device 10 illustrated in FIGS. 1A and 1B except that the passivation film 18 is further disposed on the gate insulating film 13, the source electrode 15 and the drain electrode 16.

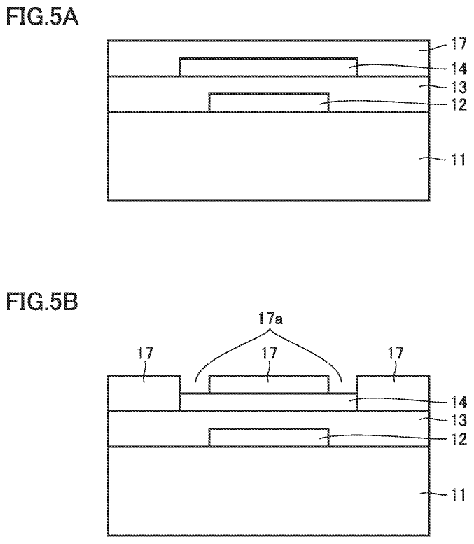

Next, an exemplary method of manufacturing the semiconductor device according to the present embodiment will be described. The method of manufacturing the semiconductor device includes a step of preparing the sputtering target of the above embodiment and a step of forming the oxide semiconductor film by a sputtering method using the sputtering target. First, the method of manufacturing the semiconductor device 10 illustrated in FIGS. 1A and 1B will be described. Although the manufacturing method is not particularly limited, from the viewpoint of efficiently manufacturing the semiconductor device 10 with excellent characteristics, with reference to FIGS. 4A to 4D, it is preferred that the manufacturing method includes a step of forming the gate electrode 12 on the substrate 11 (FIG. 4A), a step of forming the gate insulating film 13 as a insulating layer on the gate electrode 12 and the substrate 11 (FIG. 4B), a step of forming the oxide semiconductor film 14 as a channel layer on the gate insulating film 13 (FIG. 4C), and a step of forming the source electrode 15 and the drain electrode 16 on the oxide semiconductor film 14 without contacting each other (FIG. 4D).

(1) Step of Forming Gate Electrode

With reference to FIG. 4A, the gate electrode 12 is formed on the substrate 11. The substrate 11 is not particularly limited, but from the viewpoint of improving the transparency, the price stability and the surface smoothness, it is preferably a quartz glass substrate, a non-alkali glass substrate, an alkali glass substrate or the like. The gate electrode 12 is not particularly limited, but from the viewpoint of having a high oxidation resistance and a low electric resistance, it is preferably a Mo electrode, a Ti electrode, a W electrode, an Al electrode, a Cu electrode or the like. The method of forming the gate electrode 12 is not particularly limited, but from the viewpoint of uniformly forming the gate electrode 12 with a large area on the main surface of the substrate 11, it is preferable to use a vacuum vapor deposition method, a sputtering method or the like. As illustrated in FIG. 4A, in the case of forming the gate electrode 12 partially on the surface of the substrate 11, an etching method using a photoresist may be adopted.

(2) Step of Forming Gate Insulating Film

With reference to FIG. 4B, the gate insulating film 13 is formed as an insulating layer on the gate electrode 12 and the substrate 11. The method of forming the gate insulating film 13 is not particularly limited, but from the viewpoint of uniformly forming the gate insulating film 13 with a large area and ensuring the insulating property, it is preferable to use a plasma CVD (Chemical Vapor Deposition) method or the like.

The material for the gate insulating film 13 is not particularly limited, but from the viewpoint of ensuring the insulating property, it is preferably silicon oxide (SiOₓ), silicon nitride (SiN_{y}) or the like.

(3) Step of Forming Oxide Semiconductor Film

With reference to FIG. 4C, the oxide semiconductor film 14 is formed as a channel layer on the gate insulating film 13. As described above, the oxide semiconductor film 14 is formed in a film formation process by the sputtering method. As the raw material target (sputtering target) for the sputtering method, the oxide sintered material of Embodiment 1 is used.

In order to obtain excellent characteristics (for example, the reliability under light irradiation) when it is used as a semiconductor device, it is preferable to perform a heat treatment (annealing) after the film formation by the sputtering method. The heat treatment may be performed immediately after the formation of the oxide semiconductor film 14 or after the formation of the source electrode 15, the drain electrode 16, the etch stopper layer 17, the passivation film 18 or the like.

In order to obtain excellent characteristics (for example, the reliability under light irradiation) when it is used as a semiconductor device, it is more preferable to perform the heat treatment after forming the etch stopper layer 17. If the heat treatment is performed after forming the etch stopper layer 17, the heat treatment may be performed before or after the formation of the source electrode 15 and the drain electrode 16, but preferably before the formation of the passivation film 18.

(4) Step of Forming Source Electrode and Drain Electrode

With reference to FIG. 4D, the source electrode 15 and the drain electrode 16 are formed on the oxide semiconductor film 14 without contacting each other. Each of the source electrode 15 and the drain electrode 16 is not particularly limited, but from the viewpoint of having a high oxidation resistance, a low electric resistance and a low contact electric resistance with the oxide semiconductor film 14, it is preferably a Mo electrode, a Ti electrode, a W electrode, an Al electrode, a Cu electrode or the like. The method of forming the source electrode 15 and the drain electrode 16 is not particularly limited, but from the viewpoint of uniformly forming the source electrode 15 and the drain electrode 16 with a large area on the oxide semiconductor film 14 formed on the main surface of the substrate 11, it is preferable to use a vacuum vapor deposition method, a sputtering method or the like. The method of forming the source electrode 15 and the drain electrode 16 without contacting each other is not particularly limited, but from the viewpoint of forming a uniform pattern of the source electrode 15 and the drain electrode 16 with a large area, an etching method using a photoresist is preferable.

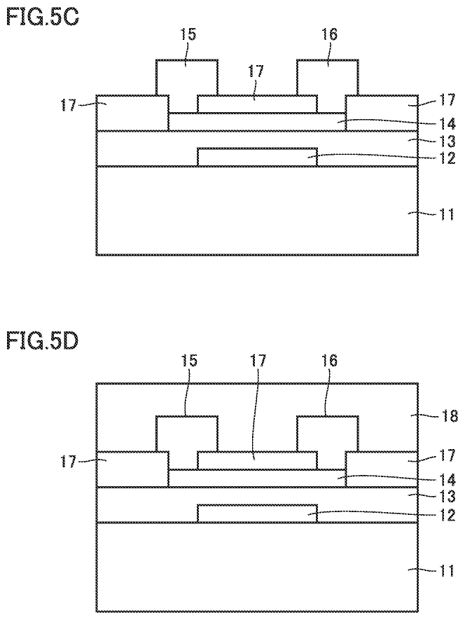

Next, a method of manufacturing the semiconductor device 20 illustrated in FIG. 2 will be described. The method of manufacturing the semiconductor device 20 is the same as the method of manufacturing the semiconductor device 10 illustrated in FIGS. 1A and 1B except that it further includes a step of forming the etch stopper layer 17 provided with a contact hole 17a and a step of forming the passivation film 18. Specifically, with reference to FIGS. 4A to 4D and FIGS. 5A to 5 D, it is preferable that the method of manufacturing the semiconductor device 20 includes a step of the gate electrode 12 on the substrate 11 (FIG. 4A), a step of forming the gate insulating film 13 as an insulating layer on the gate electrode 12 and the substrate 11 (FIG. 4B), a step of forming the oxide semiconductor film 14 as a channel layer on the gate insulating film 13 (FIG. 4C), a step of forming the etch stopper layer 17 on the oxide semiconductor film 14 and the gate insulating film 13 (FIG. 5A), a step of forming the contact hole 17a in the etch stopper layer 17 (FIG. 5B), a step of forming the source electrode 15 and the drain electrode 16 on the oxide semiconductor film 14 and the etch stopper layer 17 without contacting each other (FIG. 5C), and a step of forming the passivation film 18 on the etch stopper layer 17, the source electrode 15 and the drain electrode 16 (FIG. 5D).

The material for the etch stopper layer 17 is not particularly limited, but from the viewpoint of ensuring the insulating property, it is preferably silicon oxide (SiOₓ), silicon nitride (SiN_{y}), aluminum oxide (AlₘOₙ) or the like. The etch stopper layer 17 may be a combination of films made of different materials. The method of forming the etch stopper layer 17 is not particularly limited, but from the viewpoint of uniformly forming the etch stopper layer 17 with a large area and ensuring the insulation property, it is preferable to use a plasma CVD (Chemical Vapor Deposition) method, a sputtering method, a vacuum vapor deposition method or the like.

Since it is necessary to bring the source electrode 15 and the drain electrode 16 into contact with the oxide semiconductor film 14, after forming the etch stopper layer 17 on the oxide semiconductor film 14, the contact hole 17a is formed in the etch stopper layer 17 (FIG. 5B). As a method of forming the contact hole 17a, a dry etching method or a wet etching method may be given. By etching the etch stopper layer 17 according to the dry etching method or the wet etching method so as to form the contact hole 17a, the surface of the oxide semiconductor film 14 is exposed at the etched portion.

In the method of manufacturing the semiconductor device 20 illustrated in FIG. 2, similar to the manufacturing method of the semiconductor device 10 illustrated in FIGS. 1A and 1B, after the source electrode 15 and the drain electrode 16 are formed on the oxide semiconductor film 14 and the etch stopper layer 17 without contacting each other (FIG. 5C), the passivation film 18 is formed on the etch stopper layer 17, the source electrode 15 and the drain electrode 16 (FIG. 5D).

The material for the passivation film 18 is not particularly limited, but from the viewpoint of ensuring the insulating property, it is preferably silicon oxide (SiOₓ), silicon nitride (SiN_{y}), aluminum oxide (AlₘOₙ) or the like. The passivation film 18 may be a combination of films made of different materials. The method of forming the passivation film 18 is not particularly limited, but from the viewpoint of uniformly forming the passivation film 18 with a large area and ensuring the insulation property, it is preferable to use a plasma CVD (Chemical Vapor Deposition) method, a sputtering method, a vacuum vapor deposition method or the like.

Further, as the semiconductor device 30 illustrated in FIG. 3, it is acceptable that a back channel etch (BCE) structure is adopted, and instead of forming the etch stopper layer 17, the passivation film 18 is directly formed on the gate insulating film 13, the oxide semiconductor film 14, the source electrode 15 and the drain electrode 16. In this case, the passivation film 18 may be the same as the passivation film 18 of the semiconductor device 20 illustrated in FIG. 2.

(5) Other Steps

Finally, the heat treatment (annealing) is performed. The heat treatment may be carried out by heating the semiconductor device formed on the substrate.

The temperature for heating the semiconductor device in the heat treatment is preferably 100° C. or more and 500° C. or less, and more preferably 400° C. or more. The atmosphere for the heat treatment may be any atmosphere such as air atmosphere, nitrogen gas, nitrogen gas-oxygen gas, Ar gas, Ar-oxygen gas, water vapor-containing atmosphere, water vapor-containing nitrogen or the like. Preferably, it is an inert atmosphere such as nitrogen or Ar gas. The pressure of the atmosphere may be air pressure, under a depressurized condition (for example, less than 0.1 Pa), or under a pressurized condition (for example, 0.1 Pa to 9 MPa), but it is preferably air pressure. The time for the heat treatment may be, for example, about 3 minutes to 2 hours, and preferably about 10 minutes to 90 minutes.

In order to obtain excellent characteristics (for example, the reliability under light irradiation) when it is used as a semiconductor device, it is desirable that the heat treatment is performed at a higher temperature. However, if the temperature for the heat treatment is raised, the field-effect mobility of the In—Ga—Zn—O-based oxide semiconductor film may be deteriorated. However, if a semiconductor device (for example, a TFT) includes, as a channel layer, the oxide semiconductor film 14 obtained by the sputtering method using the oxide sintered material according to Embodiment 1 as a sputtering target, it is possible for the semiconductor device to maintain a high field-effect mobility even if it is annealed at a high temperature, which is advantageous.

### EXAMPLES

### Examples 1 to 39

(1) Production of Oxide Sintered Material

(1-1) Preparation of Raw Powders

The following powders were prepared: tungsten oxide powder (denoted as “W” in Table 1 or Table 2) having a composition (listed in the column of “W powder” in Table 1 or Table 2), a median particle size d50 (denoted as in the column of “W Particle Size” in Table 1 or Table 2) and a purity of 99.99 mass %; ZnO powder (denoted as “Z” in Table 1 or Table 2) having a median particle size d50 of 1.0 μm and a purity of 99.99 mass %; In₂O₃ powder (denoted as “I” in Table 1 or Table 2) having a median particle size d50 of 1.0 μm and a purity of 99.99 mass %; and ZrO₂ powder (denoted as “R” in Table 1 or Table 2) having a median particle size d50 of 1.0 μm and a purity of 99.99 mass %.

(1-2) Preparation of Calcined Powder Containing In₂(ZnO)ₘO₃ Crystal Phase

First, the In₂O₃ powder and the ZnO powder among the prepared raw powders were introduced into a ball mill and were pulverized and mixed for 18 hours to prepare a primary mixture of the raw powders. The In₂O₃ powder and the ZnO powder were mixed such that the molar mixing ratio of the In₂O₃ powder:the ZnO powder is approximately 1:3-5. During the pulverization and mixing, ethanol was used as a dispersion medium. The obtained primary mixture of the raw powders was dried in air.

Next, the obtained primary mixture of the raw powders was charged into an alumina crucible and calcined in the air atmosphere for 8 hours at a calcination temperature shown in Table 1 or Table 2 to obtain a calcined powder containing In₂(ZnO)₃₋₅O₃ crystal phase. The In₂(ZnO)₃₋₅O₃ crystal phase was identified by X-ray diffraction measurement. The conditions for the X-ray diffraction measurement are the same as those listed in the following (2-1).

(1-3) Preparation of Calcined Powder Containing In₆WO₁₂ Crystal Phase

First, the In₂O₃ powder and the WO_{2.72} powder among the prepared raw powders were introduced into a ball mill and were pulverized and mixed for 18 hours to prepare a primary mixture of the raw powders. The In₂O₃ powder and the WO_{2.72} powder were mixed such that the molar mixing ratio of the In₂O₃ powder:the WO_{2.72} powder is approximately =3:1. During the pulverization and mixing, ethanol was used as a dispersion medium. The obtained primary mixture of the raw powders was dried in air.

Next, the obtained primary mixture of the raw powders was charged into an alumina crucible and calcined in the air atmosphere for 8 hours at a calcination temperature shown in Table 1 or Table 2 to obtain a calcined powder containing In₆WO₁₂ crystal phase. The In₆WO₁₂ crystal phase was identified by X-ray diffraction measurement. The conditions for the X-ray diffraction measurement are the same as those listed in the following (2-1).

(1-4) Preparation of Secondary Mixture of Raw Powders Including Calcined Powder

Next, the obtained calcined powder was charged into a pot together with the remainder of the prepared raw powders, i.e., the In₂O₃ powder, the ZnO powder, the tungsten oxide powder and the ZrO₂ powder, which were then introduced into a pulverization mixing ball mill and were pulverized and mixed for 12 hours to prepare a secondary mixture of the raw powders.

When the calcined powder contains the In₂(ZnO)₃₋₅O₃ crystal phase, the ZnO powder was not used.

When the calcined powder contains the In₆WO₁₂ crystal phase, the tungsten oxide powder was not used.

Moreover, in Example 6, the ZrO₂ powder was not used.

In the column of “calcined powder” in Table 1 and Table 2, when the calcined powder contains the In₂(ZnO)₃O₃ crystal phase, it is denoted as “IZ3”; when the calcined powder contains the In₂(ZnO)₄O₃ crystal phase, it is denoted as “IZ4”; when the calcined powder contains the In₂(ZnO)₅O₃ crystal phase, it is denoted as “IZ5”; and when the calcined powder contains the In₆WO₁₂ crystal phase, it is denoted as “IW”.

The mixing ratio of the raw powders was set such that the molar ratio of In, Zn, W and Zr in the mixture was as shown in Table 1 or Table 2. During the pulverization and mixing, pure water was used as a dispersion medium. The obtained mixed powder was dried by spray drying.

(1-5) Formation of Molded Body by Molding Secondary Mixture

Next, the obtained raw powder mixture was molded by pressing, and then press-molded according to the OP method in static water at room temperature (5° C. to 30° C.) under a pressure of 190 MPa to obtain a disk-shaped molded body which contains In, W and Zn and has a diameter of 100 mm and a thickness of about 9 mm.

(1-6) Formation of Oxide Sintered Material (Sintering Step)

Next, the obtained molded body was sintered for 8 hours at a sintering temperature (the second temperature) shown in Table 1 or Table 2 in the air atmosphere under air pressure to obtain an oxide sintered material containing an In₂O₃ crystal phase, an In₂(ZnO)ₘO₃ crystal phase and a ZnWO₄ crystal phase. The second temperature described in Table 1 and Table 2 is the maximum temperature in the sintering step.

The retention temperature (the first temperature) in the cooling process of the sintering step is shown in Table 1 or Table 2. The atmosphere (oxygen concentration and relative humidity) at the first temperature and the retention time are also shown in Table 1 or Table 2. The relative humidity is converted to the equivalent value at 25° C. The pressure of the atmosphere at the first temperature was equal to the air pressure.

(2) Evaluation of Physical Properties of Oxide Sintered Material

(2-1) Identification of In₂O₃ Crystal Phase, In₂(ZnO)ₘO₃ Crystal Phase and ZnWO₄ Crystal Phase

A sample was taken from a portion having a depth of 2 mm or more from the outermost surface of the obtained oxide sintered material and subjected to crystal analysis by X-ray diffraction method. The measurement conditions for X-ray diffraction were as follows.

(Measurement Conditions of X-Ray Diffraction)

θ-2θ method,

X-ray source: Cu Kα ray,

X-ray tube voltage: 45 kV,

X-ray tube current: 40 mA,

Step width: 0.02°,

Step time: 1 second/step,

Measurement range 20:10° to 80°.

According to the identification of the diffraction peaks, it was confirmed that the oxide sintered material of each of Examples 1 to 39 contains all of the In₂O₃ crystal phase, the In₂(ZnO)ₘO₃ crystal phase and the ZnWO₄ crystal phase.

(2-2) Content of Each Crystal Phase

According to the RIR method based on the X-ray diffraction measurement described in the above (2-1), the content (mass %) of each of the In₂O₃ crystal phase (I crystal phase), the In₂(ZnO)ₘO₃ crystal phase (IZ crystal phase) and the ZnWO₄ crystal phase (ZW crystal phase) in the oxide sintered material was quantified. The results are shown as in “I”, “IZ” and “ZW” under the column of “content of crystal phase” in Table 3 or Table 4, respectively. The number m of the In₂(ZnO)ₘO₃ crystal phase is shown in the column of “m” in Table 3 or Table 4.

(2-3) Element Content in Oxide Sintered Material

The contents of In, Zn, W and Zr in the oxide sintered material were measured by ICP emission spectrometry. Further, the Zn/W ratio (the ratio of the Zn content relative to the W content) was calculated from the obtained Zn content and W content. The results are shown in “In”, “Zn”, “W”, “Zr”, “Zn/W ratio” under the column of “element content” in Table 3 or Table 4, respectively. The unit of the In content, the Zn content and the W content is atom %, the unit of the Zr content is ppm in terms of the number of atoms, and the Zn/W ratio is the ratio of atom numbers.

(2-4) Amount of Pores in Oxide Sintered Material

A sample was taken from a portion having a depth of 2 mm or more from the outermost surface of the oxide sintered material immediately after sintering. The obtained sample was ground by using a surface grinding machine, the surface of the sample was polished by using a lapping machine, and finally polished by using a cross section polisher, and then subjected to SEM observation. The pores appears black in a backscattered electron image observed under a field of view of 500 times. The image was binarized, and the ratio of the area of the black portions relative to the whole area of the image was calculated. Three fields of view were selected such that the regions did not overlap, and the average value of the area ratios for these regions was calculated as the amount of pores (area %). The results are shown in the column of “amount of pores” in Table 3 or Table 4.

(2-5) Average Number of Oxygen Atoms Coordinated to Indium Atom

The average number of oxygen atoms coordinated to the indium atom in the oxide sintered material was measured according to the measurement method mentioned above. The results are shown in the column of “oxygen coordination number” in Table 3 or Table 4.

(3) Preparation of Sputtering Target

The obtained oxide sintered material was processed to have a size of 3 inches (76.2 mm) in diameter×6 mm in thickness, and then attached to a copper backing plate using indium metal.

(4) Preparation and Evaluation of Semiconductor Device (TFT) Including Oxide Semiconductor Film

(4-1) Measurement of Arcing Frequency During Sputtering

The prepared sputtering target was placed in a film deposition chamber of a sputtering apparatus. The sputtering target was water cooled through the intermediary of the copper backing plate. The film deposition chamber was depressurized to have a degree of vacuum of about 6×10⁻⁵ Pa, and the target was sputtered as follows.

Ar (argon) gas only was introduced into the film formation chamber until the inner pressure reached 0.5 Pa. DC power of 450 W was applied to the target so as to induce a sputtering discharge and held for 60 minutes. The sputtering discharge was continuously induced for 30 minutes. The arcing frequency was measured by using an arc counter (arcing frequency counting device) attached to the DC power supply. The results are shown in the column of “arcing frequency” in Table 5 or Table 6.

(4-2) Preparation of Semiconductor Device (TFT) Including Oxide Semiconductor Film

A TFT having a similar structure to the semiconductor device 30 illustrated in FIG. 3 was prepared by the following procedure. With reference to FIG. 4A, first, a synthetic quartz glass substrate having a dimension of 75 mm×75 mm×0.6 mm in thickness was prepared as the substrate 11, and a Mo electrode having a thickness of 100 nm was formed on the substrate 11 according to a sputtering method as the gate electrode 12. Next, as illustrated in FIG. 4A, the gate electrode 12 was processed into a predetermined shape through etching by using a photoresist.

Next, with reference to FIG. 4B, a SiOₓ, film having a thickness of 200 nm was formed on the gate electrode 12 and the substrate 11 according to the plasma CVD method as the gate insulating film 13.

Next, with reference to FIG. 4C, the oxide semiconductor film 14 with a thickness of 30 nm was formed on the gate insulating film 13 according to the DC (direct current) magnetron sputtering method. A flat surface of the target with a diameter of 3 inches (76.2 mm) was used as the sputtering surface. The oxide sintered material obtained in the above (1) was used as the target.

The formation of the oxide semiconductor film 14 will be described in more detail. On a substrate holder which is water-cooled in the film deposition chamber of a sputtering apparatus (not shown), the substrate 11, on which the gate electrode 12 and the gate insulating film 13 are formed, was arranged in such a manner that the gate insulating film 13 was exposed. The target was disposed to face the gate insulating film 13 with a distance of 90 mm. The film deposition chamber was depressurized to have a degree of vacuum of about 6×10⁻⁵ Pa, and the target was sputtered as follows.

First, in a state in which a shutter was inserted between the gate insulating film 13 and the target, a gas mixture of Ar (argon) gas and O₂ (oxygen) gas was introduced into the film formation chamber until the inner pressure reached 0.5 Pa. The content of O₂ gas in the gas mixture was 20% by volume. DC power 450 W was applied to the sputtering target to induce sputtering discharge so as to clean (pre-sputter) the surface of the target for 5 minutes.

Next, while the DC power of the same value as described in the above was being applied to the same target as described in the above and the atmosphere in the film formation chamber was maintained to be unchanged, the shutter was removed so as to form the oxide semiconductor film 14 on the gate insulating film 13. It should be noted that no bias voltage was particularly applied to the substrate holder. Moreover, the substrate holder was water cooled.

As described above, the oxide semiconductor film 14 was formed by the DC (direct current) magnetron sputtering method using the target manufactured from the oxide sintered material obtained in the above (1). The oxide semiconductor film 14 serves as a channel layer in the TFT. The film thickness of the oxide semiconductor film 14 was 30 nm (the same applies to the other examples and comparative examples).

Next, the obtained oxide semiconductor film 14 was partially etched to form a source electrode formation portion 14s, a drain electrode formation portion 14d, and a channel portion 14c. The size of the main surface of each of the source electrode formation portion 14s and the drain electrode formation portion 14d was set to 50 μm×50 μm, a channel length C_{L} (with reference to FIG. 1A and FIG. 1B, the channel length C_{L} refers to a distance of the channel portion 14c between the source electrode 15 and the drain electrode 16) was set to 30 μm, and a channel width C_{W} (with reference to FIG. 1A and FIG. 1B, the channel width C_{W} refers to the width of the channel portion 14c) was set to 40 μm. A number of 25 (at the longitudinal side)×25 (at the lateral side) of the channel portions 14c were disposed on the substrate main surface of 75 mm×75 mm at a spacing of 3 mm such that a number of 25 (at the longitudinal side)×25 (at the lateral side) of TFTs were disposed on the substrate main surface of 75 mm×75 mm at a spacing of 3 mm.

The oxide semiconductor film 14 was partially etched in the following manner: an etching aqueous solution was prepared to have a volume ratio of oxalic acid:water=5:95, the substrate 11 having the gate electrode 12, the gate insulating film 13 and the oxide semiconductor film 14 formed thereon in this order was immersed in the etching aqueous solution at 40° C.

With reference to FIG. 4D, the source electrode 15 and the drain electrode 16 were then formed on the oxide semiconductor film 14, separating from each other.

Specifically, first, a resist (not shown) was applied onto the oxide semiconductor film 14, exposed to light and developed so as to expose only the main surface of the oxide semiconductor film 14 corresponding to the source electrode formation portion 14s and the drain electrode formation portion 14d. Next, the sputtering method was employed to form Mo electrodes each having a thickness of 100 nm and serving as the source electrode 15 and the drain electrode 16 respectively on the main surface of the oxide semiconductor film 14 corresponding to the source electrode formation portion 14s and the drain electrode formation portion 14d. Then, the resist developed on the oxide semiconductor film 14 was removed. One Mo electrode serving as the source electrode 15 and one Mo electrode serving as the drain electrode 16 were formed for one channel portion 14c such that a number of 25 (at the longitudinal side)×25 (at the lateral side) of TFTs were disposed on the substrate main surface of 75 mm×75 mm at a spacing of 3 mm.

Next, with reference to FIG. 3, the passivation film 18 was formed on the gate insulating film 13, the oxide semiconductor film 14, the source electrode 15, and the drain electrode 16. The passivation film 18 was formed by forming a SiO, film with a thickness of 200 nm by the plasma CVD method and then a SiN_{y} film with a thickness of 200 nm was formed thereon by the plasma CVD method. In order to improve the reliability under light irradiation, it is desirable that the oxygen content should meet the condition that the atomic composition ratio of the SiOₓ film is closer to Si: 0=1:2.

Next, the passivation film 18 on the source electrode 15 and the drain electrode 16 was etched by reactive ion etching to form a contact hole, thereby partially exposing the surface of the source electrode 15 and the surface of the drain electrode 16.

Finally, the heat treatment (annealing) was performed in nitrogen atmosphere under the air pressure. The heat treatment was performed for all Examples and Comparative Examples. Specifically, the heat treatment (annealing) was performed in nitrogen atmosphere at 350° C. for 60 minutes or in nitrogen atmosphere at 450° C. for 60 minutes. Thus, a TFT including the oxide semiconductor film 14 as a channel layer was obtained.

(4-3) Average Number of Oxygen Atoms Coordinated to Indium Atom

The average number of oxygen atoms coordinated to the indium atom in the oxide semiconductor film 14 included in the prepared TFT was measured according to the measurement method described above. The results are shown in the column of “oxygen coordination number” in Table 5 or Table 6.

(4-4) Crystallinity, W Content, Zn Content, and Zn/W Ratio of Oxide Semiconductor Film

The crystallinity of the oxide semiconductor film 14 included in the prepared TFT was evaluated according to the measurement method and definition described above. In the column of “Crystallinity” in Tables 5 and 6, when the oxide semiconductor film is amorphous, it is denoted as “A”, otherwise it is denoted as “C”.

The contents of In, W and Zn in the oxide semiconductor film 14 were measured by RBS (Rutherford backscattering analysis). Based on these contents, the W content (atom %), the Zn content (atom %), and the Zn/W ratio (in terms of atom numbers) of the oxide semiconductor film 14 were determined. The results are shown in the column of “element content” “In”, “Zn”, “W”, and “Zn/W ratio” in Table 5 or Table 6, respectively. The unit of the In content, the Zn content and the W content is atom %, and the Zn/W ratio is expressed in terms of atom numbers.

The Zr content in the oxide semiconductor film 14 was measured by using ICP-MS (ICP mass spectrometer) in accordance with the measurement method described above. The results are shown in the column of “Zr” under “element content” in Table 5 or Table 6. The unit of the Zr content is ppm in terms of mass.

(4-5) Evaluation on Characteristics of Semiconductor Device

The characteristics of the TFT serving as the semiconductor device 10 were evaluated as follows. First, a measurement needle was brought into contact with the gate electrode 12, the source electrode 15 and the drain electrode 16, respectively. While a source-drain voltage Vas of 0.2 V was being applied between the source electrode 15 and the drain electrode 16, a source-gate voltage V_{gs} applied between the source electrode 15 and the gate electrode 12 was varied from −10 V to 15 V to measure a source-drain current Ids. Thereby, a graph was created with the horizontal axis representing the source-gate voltage V_{gs} and the vertical axis representing the source-drain current Ids.

Moreover, gₘ was derived by differentiating the source-drain current Ids with respect to the source-gate voltage V_{gs} in accordance with the following formula [a]:

gₘ=dI_{ds}/dV_{gs} [a]

Then, the value of gₘ when V_{gs}=10.0 V was used to determine the field effect mobility μ_{fe} based on the following formula [b]:

μ_{fe}=gₘ·C_{L}/(C_{W}·Cᵢ·V_{ds}) [b]

In the above formula [b], the channel length CL was 30 μm and the channel width C_{W} was 40 Moreover, the capacitance Cᵢ of the gate insulating film 13 was set to 3.4×10⁻⁸ F/cm², and the source-drain voltage Vas was set to 0.2 V.

The field-effect mobility μ_{fe} after the heat treatment (annealing) at 350° C. for 60 minutes in the nitrogen atmosphere under the atmospheric pressure is shown in the column of “mobility (350° C.)” in Table 5 or Table 6, and the field-effect mobility μ_{fe} after the heat treatment (annealing) at 450° C. for 10 minutes in the nitrogen atmosphere under the atmospheric pressure is shown in the column of “mobility (450° C.)” in Table 5 or Table 6. Further, the ratio of the field-effect mobility after the heat treatment at 450° C. relative to the field-effect mobility after the heat treatment at 350° C. (ratio of mobility (450° C.)/mobility (350° C.)) is shown in the column of “mobility ratio” in Table 5 or Table 6.

Furthermore, the following test for evaluating the reliability under light irradiation was performed. While the TFT is being irradiated by a light beam with a wavelength of 460 nm from the top of the TFT at an intensity of 0.25 mW/cm², the source-gate voltage V_{gs} between the source electrode 15 and the gate electrode 12 is fixed at −30 V and continued for 1 hour. The threshold voltage Vₜₕ was determined 1 second, 10 seconds, 100 seconds, 300 seconds, and 4000 seconds after the application of voltage, and the difference ΔVₜₕ between the maximum threshold voltage Vₜₕ and the minimum threshold voltage Vₜₕ was determined. It is determined that as the ΔVₜₕ becomes smaller, the reliability under light irradiation becomes higher. The ΔVₜₕ determined after the heat treatment was performed at 350° C. for 10 minutes in the nitrogen atmosphere under air pressure are shown in the column of “ΔVₜₕ (350° C.)” in Table 5 or Table 6, and the ΔVₜₕ determined after the heat treatment was performed at 450° C. for 10 minutes in the nitrogen atmosphere under air pressure are shown in the column of “ΔVₜh (450° C.)” in Table 5 or Table 6.

The threshold voltage Vₜₕ was determined as follows. First, a measurement needle was brought into contact with the gate electrode 12, the source electrode 15 and the drain electrode 16. While a source-drain voltage V_{ds} of 0.2 V was being applied between the source electrode 15 and the drain electrode 16, a source-gate voltage V_{gs} applied between the source electrode 15 and the gate electrode 12 is changed from −10 V to 15 V, the source-drain current Ids at that time was measured. Then, the relationship between the source-gate voltage V_{gs} and the square root of the source-drain current Ids [(Ids)^{′2}] was graphed (hereinafter, this graph is also referred to as “V_{gs}−(I_{ds})^{1/2} curve”). A tangent line was drawn tangent to the V_{gs}−(I_{ds})^{1/2} curve at a point where the slope of the tangent line is the maximum, and an intersection point (x intercept) where the tangent line intersects with the x axis (V_{gs}) was determined as the threshold voltage Vₜₕ.

The reliability of a thin film transistor is generally evaluated by a negative bias stress test (NBS), a positive bias stress test (PBS), or a negative bias illumination stress test (NBIS). NBS and PBS are mainly affected by the electron capture density at the interface between the semiconductor layer and the gate insulating film or the interface between the semiconductor layer and the passivation film, while in NBIS, the reliability (Vₜₕ shift) is affected by the density of electrons that are excited by light. Thus, NBS, PBS and NBIS are different at the cause of the Vₜₕ shift.

### Comparative Example 1 and Comparative Example 2

An oxide sintered material was prepared according to Table 1. The semiconductor device was prepared and evaluated in the same manner as in Examples 1 to 39 except that the prepared oxide sintered material was used. The measurement results and the evaluation results for the same items as those in Examples 1 to 39 are shown in Table 1, Table 3 and Table 5.

In Comparative Example 1, the molded body was not placed at the first temperature for 2 hours or more in the sintering step, and after the sintering treatment for 8 hours at the second temperature, the cooling rate was set higher than 150° C./h. During the cooling process, the atmosphere in the temperature range of 300° C. or more and less than 600° C. had a pressure equal to the air pressure, an oxygen concentration of 35%, and a relative humidity (equivalent value at 25° C.) of 60 RH %.

In Comparative Example 2, the molded body was placed at the first temperature for 2 hours or more in the sintering step. During the cooling process, the atmosphere in the temperature range of 300° C. or more and less than 600° C. was the air atmosphere (therefore, the pressure was equal to the air pressure), and the relative humidity (at 25° C.) thereof was 30 RH %.

TABLE 1

| | | Molar Mixing Ratio | | | | | W | | | First | | Oxygen | | Second |
|---|---|---|---|---|---|---|---|---|---|---|---|---|---|---|
| | | I | Z | W | R | | Particle | Calcination | | Temper- | Retention | Concen- | Relative | Temper- |
| | | (mol. | (mol. | (mol. | (mol. | W | Size | Temperature | Calcined | ature | Time | tration | Humidity | ature |
| | | %) | %) | %) | %) | Powder | (μm) | (° C.) | Powder | (° C.) | (h) | (%) | (% RH) | (° C.) |
| Example | 1 | 68.03 | 31.92 | 0.02 | 0.04 | WO2 | 1.1 | 1200 | IW | 400 | 4 | 50 | 85 | 1180 |
| Example | 2 | 67.90 | 31.89 | 0.17 | 0.04 | WO2 | 1.1 | 1200 | IW | 450 | 4 | 50 | 85 | 1180 |
| Example | 3 | 67.33 | 31.78 | 0.84 | 0.05 | WO2 | 1 | 1200 | IW | 550 | 4 | 35 | 60 | 1180 |
| Example | 4 | 67.18 | 31.71 | 0.83 | 0.28 | WO2 | 1 | 1200 | IW | 550 | 4 | 35 | 60 | 1180 |
| Example | 5 | 67.03 | 31.64 | 0.83 | 0.50 | WO2 | 1 | 1200 | IW | 550 | 4 | 35 | 60 | 1180 |
| Example | 6 | 67.36 | 31.80 | 0.84 | 0.00 | WO2 | 1 | 1200 | IW | 550 | 4 | 35 | 60 | 1180 |
| Example | 7 | 67.33 | 31.79 | 0.84 | 0.04 | WO3 | 1 | 1200 | IW | 550 | 4 | 35 | 60 | 1195 |
| Example | 8 | 67.33 | 31.78 | 0.84 | 0.05 | WO2.72 | 1 | 1200 | IW | 550 | 4 | 35 | 60 | 1180 |
| Example | 9 | 66.64 | 31.65 | 1.67 | 0.04 | WO2 | 0.9 | 1200 | IW | 500 | 4 | 45 | 80 | 1180 |
| Example | 10 | 66.37 | 31.60 | 2.00 | 0.03 | WO2 | 1.5 | 1200 | IW | 500 | 4 | 45 | 50 | 1180 |
| Example | 11 | 65.26 | 31.39 | 3.30 | 0.05 | WO2 | 1.8 | 1200 | IW | 500 | 4 | 45 | 50 | 1180 |
| Example | 12 | 57.45 | 29.90 | 12.59 | 0.06 | WO2 | 2 | 1200 | IW | 500 | 4 | 45 | 50 | 1180 |
| Example | 13 | 52.65 | 28.99 | 18.31 | 0.05 | WO2 | 1.5 | 1200 | IW | 500 | 4 | 45 | 50 | 1180 |
| Example | 14 | 94.10 | 5.82 | 0.02 | 0.05 | WO2 | 1.2 | 1200 | IZ3 | 400 | 4 | 50 | 85 | 1180 |
| Example | 15 | 93.95 | 5.82 | 0.19 | 0.04 | WO2 | 1.2 | 1200 | IZ3 | 400 | 4 | 50 | 85 | 1180 |
| Example | 16 | 93.18 | 5.79 | 0.97 | 0.06 | WO2 | 1.5 | 1200 | IW | 550 | 4 | 35 | 60 | 1180 |
| Example | 17 | 90.44 | 5.71 | 3.81 | 0.04 | WO2 | 0.8 | 1200 | IZ3 | 500 | 4 | 45 | 50 | 1180 |
| Example | 18 | 51.48 | 48.46 | 0.02 | 0.05 | WO2 | 1 | 1200 | IZ4 | 450 | 4 | 50 | 85 | 1180 |
| Example | 19 | 51.37 | 48.42 | 0.15 | 0.05 | WO2 | 1 | 1200 | IZ4 | 450 | 4 | 50 | 85 | 1180 |
| Example | 20 | 50.92 | 48.28 | 0.75 | 0.04 | WO2 | 1.3 | 1200 | IW | 550 | 4 | 35 | 60 | 1180 |
| Example | 21 | 50.35 | 48.09 | 1.50 | 0.05 | WO2 | 0.7 | 1200 | IZ5 | 500 | 4 | 45 | 50 | 1180 |
| Example | 22 | 50.13 | 48.02 | 1.80 | 0.05 | WO2 | 1.4 | 1200 | IZ5 | 500 | 4 | 45 | 50 | 1180 |
| Example | 23 | 63.89 | 36.05 | 0.02 | 0.05 | WO2 | 1.1 | 1200 | IW | 400 | 4 | 50 | 85 | 1180 |
| Example | 24 | 63.77 | 36.02 | 0.16 | 0.04 | WO2 | 1.1 | 1200 | IW | 400 | 4 | 50 | 85 | 1180 |
| Example | 25 | 63.24 | 35.90 | 0.82 | 0.05 | WO2 | 1.2 | 1200 | IW | 550 | 4 | 35 | 60 | 1180 |
| Example | 26 | 62.57 | 35.76 | 1.63 | 0.04 | WO2 | 1.6 | 1200 | IW | 500 | 4 | 45 | 50 | 1180 |
| Example | 27 | 62.31 | 35.70 | 1.95 | 0.05 | WO2 | 1.4 | 1200 | IW | 500 | 4 | 45 | 50 | 1180 |
| Compar- | 1 | 67.33 | 31.78 | 0.84 | 0.05 | WO2 | 1 | 1200 | IW | — | — | 35 | 60 | 1180 |
| ative | | | | | | | | | | | | | | |
| Example | | | | | | | | | | | | | | |
| Compar- | 2 | 67.33 | 31.78 | 0.84 | 0.05 | WO2 | 1 | 1200 | IW | 550 | 4 | air | 30 | 1180 |
| ative | | | | | | | | | | | | | | |
| Example | | | | | | | | | | | | | | |

TABLE 2

| | | Molar Mixing Ratio | | | | | W | | | First | | Oxygen | | Second |
|---|---|---|---|---|---|---|---|---|---|---|---|---|---|---|
| | | I | Z | W | R | | Particle | Calcination | | Temper- | Retention | Concen- | Relative | Temper- |
| | | (mol. | (mol. | (mol. | (mol. | W | Size | Temperature | Calcined | ature | Time | tration | Humidity | ature |
| | | %) | %) | %) | %) | Powder | (μm) | (° C.) | Powder | (° C.) | (h) | (%) | (% RH) | (° C.) |
| Example | 28 | 40.82 | 59.13 | 0.02 | 0.04 | WO2 | 1.1 | 1200 | IW | 400 | 4 | 50 | 85 | 1180 |
| Example | 29 | 40.73 | 59.09 | 0.14 | 0.04 | WO2 | 1.1 | 1200 | IW | 400 | 4 | 50 | 85 | 1180 |
| Example | 30 | 40.34 | 58.92 | 0.70 | 0.04 | WO2 | 1.2 | 1200 | IW | 550 | 4 | 35 | 60 | 1180 |
| Example | 31 | 39.85 | 58.72 | 1.40 | 0.04 | WO2 | 1.6 | 1200 | IW | 500 | 4 | 45 | 50 | 1180 |
| Example | 32 | 39.65 | 58.63 | 1.68 | 0.04 | WO2 | 1.4 | 1200 | IW | 500 | 4 | 45 | 50 | 1180 |
| Example | 33 | 28.19 | 71.76 | 0.02 | 0.04 | WO2 | 1.1 | 1200 | IW | 400 | 4 | 50 | 85 | 1180 |
| Example | 34 | 28.11 | 71.73 | 0.13 | 0.03 | WO2 | 1.1 | 1200 | IW | 400 | 4 | 50 | 85 | 1180 |
| Example | 35 | 27.79 | 71.54 | 0.64 | 0.04 | WO2 | 1.2 | 1200 | IW | 550 | 4 | 35 | 60 | 1180 |
| Example | 36 | 27.38 | 71.31 | 1.27 | 0.03 | WO2 | 1.6 | 1200 | IW | 500 | 4 | 45 | 50 | 1180 |
| Example | 37 | 27.22 | 71.22 | 1.53 | 0.04 | WO2 | 1.4 | 1200 | IW | 500 | 4 | 45 | 50 | 1180 |
| Example | 38 | 21.20 | 78.76 | 0.02 | 0.03 | WO2 | 1.1 | 1200 | IW | 400 | 4 | 50 | 85 | 1180 |
| Example | 39 | 5.21 | 94.66 | 0.11 | 0.03 | WO2 | 1.4 | 1200 | IW | 500 | 4 | 45 | 50 | 1180 |

TABLE 3

| | | Oxide Sintered Material | | | | | | | | | | |
|---|---|---|---|---|---|---|---|---|---|---|---|---|
| | | Element Content | | | | | Content of Crystal Phase | | | | Content | Oxygen |
| | | In | Zn | W | Zr | Zn/W | I | IZ | | ZW | of Pores | Coordination |
| | | (at. %) | (at. %) | (at. %) | (ppm) | Ratio | (mass %) | (mass %) | m | (mass %) | (area %) | Number |
| Example | 1 | 80.99 | 19.00 | 0.01 | 22 | 1900 | 85.47 | 14.51 | 4 | 0.01 | 1.5 | 4.2 |
| Example | 2 | 80.90 | 19.00 | 0.10 | 26 | 190 | 85.42 | 14.45 | 4 | 0.13 | 1.0 | 4.3 |
| Example | 3 | 80.50 | 19.00 | 0.50 | 28 | 38 | 85.16 | 14.17 | 4 | 0.66 | 0.6 | 4.4 |
| Example | 4 | 80.50 | 19.00 | 0.50 | 165 | 38 | 85.16 | 14.17 | 4 | 0.66 | 0.6 | 4.3 |
| Example | 5 | 80.50 | 19.00 | 0.50 | 300 | 38 | 85.16 | 14.17 | 4 | 0.66 | 0.6 | 4.2 |
| Example | 6 | 80.50 | 19.00 | 0.50 | 0 | 38 | 85.16 | 14.17 | 4 | 0.66 | 0.6 | 4.3 |
| Example | 7 | 80.50 | 19.00 | 0.50 | 26 | 38 | 85.16 | 14.17 | 4 | 0.66 | 0.9 | 4.5 |
| Example | 8 | 80.50 | 19.00 | 0.50 | 28 | 38 | 85.16 | 14.17 | 4 | 0.66 | 0.6 | 4.3 |
| Example | 9 | 80.00 | 19.00 | 1.00 | 23 | 19 | 84.85 | 13.83 | 4 | 1.33 | 0.8 | 4.4 |
| Example | 10 | 79.80 | 19.00 | 1.20 | 20 | 16 | 84.72 | 13.69 | 4 | 1.60 | 1.4 | 4.4 |
| Example | 11 | 79.00 | 19.00 | 2.00 | 30 | 10 | 84.21 | 13.12 | 4 | 2.67 | 1.5 | 4.4 |
| Example | 12 | 73.00 | 19.00 | 8.00 | 35 | 2 | 80.22 | 8.75 | 2 | 11.02 | 1.6 | 4.7 |
| Example | 13 | 69.00 | 19.00 | 12.00 | 33 | 2 | 77.43 | 5.69 | 2 | 16.88 | 1.7 | 4.9 |
| Example | 14 | 96.99 | 3.00 | 0.01 | 28 | 300 | 97.80 | 2.18 | 2 | 0.01 | 1.8 | 4.2 |
| Example | 15 | 96.90 | 3.00 | 0.10 | 22 | 30 | 97.75 | 2.12 | 2 | 0.13 | 1.8 | 4.3 |
| Example | 16 | 96.50 | 3.00 | 0.50 | 29 | 6 | 97.54 | 1.83 | 2 | 0.63 | 1.4 | 4.4 |
| Example | 17 | 95.00 | 3.00 | 2.00 | 20 | 2 | 96.71 | 0.74 | 2 | 2.55 | 1.8 | 4.4 |
| Example | 18 | 67.99 | 32.00 | 0.01 | 30 | 3200 | 74.58 | 25.41 | 4.5 | 0.01 | 1.8 | 4.2 |
| Example | 19 | 67.90 | 32.00 | 0.10 | 36 | 320 | 74.51 | 25.35 | 4.5 | 0.14 | 1.7 | 4.3 |
| Example | 20 | 67.50 | 32.00 | 0.50 | 28 | 64 | 74.23 | 25.09 | 4.5 | 0.69 | 1.5 | 4.4 |
| Example | 21 | 67.00 | 32.00 | 1.00 | 35 | 32 | 73.87 | 24.75 | 4.5 | 1.38 | 1.6 | 4.4 |
| Example | 22 | 66.80 | 32.00 | 1.20 | 33 | 27 | 73.72 | 24.62 | 4.5 | 1.66 | 2.0 | 4.4 |
| Example | 23 | 77.99 | 22.00 | 0.01 | 28 | 2200 | 83.03 | 16.95 | 4 | 0.01 | 1.6 | 4.2 |
| Example | 24 | 77.90 | 22.00 | 0.10 | 25 | 220 | 82.97 | 16.89 | 4 | 0.13 | 1.2 | 4.3 |
| Example | 25 | 77.50 | 22.00 | 0.50 | 28 | 44 | 82.71 | 16.62 | 4 | 0.67 | 0.7 | 4.4 |
| Example | 26 | 77.00 | 22.00 | 1.00 | 27 | 22 | 82.39 | 16.27 | 4 | 1.34 | 0.9 | 4.4 |
| Example | 27 | 76.80 | 22.00 | 1.20 | 32 | 18 | 82.26 | 16.13 | 4 | 1.61 | 1.5 | 4.4 |
| Comparative | 1 | 80.50 | 19.00 | 0.50 | 28 | 38 | 76.00 | ZnO | 4 | 1.20 | 3.5 | 2.6 |
| Example | | | | | | | | | | | | |
| Comparative | 2 | 80.50 | 19.00 | 0.50 | 28 | 38 | 76.00 | ZnO | 4 | 1.20 | 3.4 | 2.8 |
| Example | | | | | | | | | | | | |

TABLE 4

| | | Oxide Sintered Material | | | | | | | | | | |
|---|---|---|---|---|---|---|---|---|---|---|---|---|
| | | Element Content | | | | | Content of Crystal Phase | | | | Content | Oxygen |
| | | In | Zn | W | Zr | Zn/W | I | IZ | | ZW | of Pores | Coordination |
| | | (at. %) | (at. %) | (at. %) | (ppm) | Ratio | (mass %) | (mass %) | m | (mass %) | (area %) | Number |
| Example | 28 | 57.99 | 42.00 | 0.01 | 28 | 4200 | 65.59 | 34.39 | 4.5 | 0.01 | 1.4 | 4.2 |
| Example | 29 | 57.90 | 42.00 | 0.10 | 25 | 420 | 65.52 | 34.34 | 4.5 | 0.14 | 1.5 | 4.3 |
| Example | 30 | 57.50 | 42.00 | 0.50 | 28 | 84 | 65.21 | 34.08 | 4.5 | 0.71 | 1.6 | 4.4 |
| Example | 31 | 57.00 | 42.00 | 1.00 | 27 | 42 | 64.81 | 33.76 | 4.5 | 1.43 | 1.7 | 4.4 |
| Example | 32 | 56.80 | 42.00 | 1.20 | 32 | 35 | 64.65 | 33.63 | 4.5 | 1.71 | 2.1 | 4.4 |
| Example | 33 | 43.99 | 56.00 | 0.01 | 28 | 5600 | 52.03 | 47.96 | 5 | 0.01 | 1.5 | 4.2 |
| Example | 34 | 43.90 | 56.00 | 0.10 | 25 | 560 | 51.95 | 47.90 | 5 | 0.15 | 1.6 | 4.3 |
| Example | 35 | 43.50 | 56.00 | 0.50 | 28 | 112 | 51.59 | 47.67 | 5 | 0.74 | 1.7 | 4.4 |
| Example | 36 | 43.00 | 56.00 | 1.00 | 27 | 56 | 51.14 | 47.37 | 5 | 1.49 | 1.8 | 4.4 |
| Example | 37 | 42.80 | 56.00 | 1.20 | 32 | 47 | 50.96 | 47.25 | 5 | 1.79 | 2.2 | 4.4 |
| Example | 38 | 34.99 | 65.00 | 0.01 | 28 | 6500 | 37.17 | 62.82 | 5 | 0.02 | 2.3 | 4.2 |
| Example | 39 | 9.90 | 90.00 | 0.10 | 32 | 900 | 13.18 | 86.66 | 5 | 0.17 | 2.8 | 4.4 |

TABLE 5

| | | Oxide Semiconductor Film and Semiconductor Device | | | | | | | | | | | | |
|---|---|---|---|---|---|---|---|---|---|---|---|---|---|---|
| | | Oxygen | | Element Content | | | | | Arcing | Mobility | Mobility | | ΔVth | ΔVth |
| | | Coordination | Crystal- | In | Zn | W | Zn/W | Zr | Frequency | (350° C.) | (450° C.) | Mobility | (350° C.) | (450° C.) |
| | | Number | linity | (at. %) | (at. %) | (at.%) | Ratio | (ppm) | (times) | (cm²/Vs) | (cm²/Vs) | Ratio | (V) | (V) |
| Example | 1 | 3.4 | A | 81.74 | 18.24 | 0.02 | 829 | 328 | 1 | 58 | 60 | 1.04 | 1.45 | 1.20 |
| Example | 2 | 3.5 | A | 81.54 | 18.24 | 0.22 | 83 | 374 | 1 | 56 | 58 | 1.04 | 1.56 | 1.29 |
| Example | 3 | 3.6 | A | 80.66 | 18.24 | 1.10 | 17 | 398 | 0 | 52 | 54 | 1.04 | 1.63 | 1.35 |
| Example | 4 | 3.5 | A | 80.66 | 18.24 | 1.10 | 17 | 1578 | 0 | 52 | 54 | 1.04 | 1.66 | 1.38 |
| Example | 5 | 3.4 | A | 80.66 | 18.24 | 1.10 | 17 | 2432 | 0 | 51 | 47 | 0.92 | 1.69 | 1.40 |
| Example | 6 | 3.5 | A | 80.66 | 18.24 | 1.10 | 17 | 0 | 0 | 53 | 49 | 0.92 | 1.75 | 1.45 |
| Example | 7 | 3.7 | A | 80.66 | 18.24 | 1.10 | 17 | 374 | 3 | 44 | 46 | 1.04 | 1.66 | 1.38 |
| Example | 8 | 3.5 | A | 80.66 | 18.24 | 1.10 | 17 | 398 | 0 | 50 | 52 | 1.04 | 1.68 | 1.39 |
| Example | 9 | 3.6 | A | 79.56 | 18.24 | 2.20 | 8 | 339 | 0 | 36 | 36 | 1.00 | 1.65 | 1.37 |
| Example | 10 | 3.6 | A | 79.12 | 18.24 | 2.64 | 7 | 304 | 1 | 28 | 26 | 0.93 | 1.74 | 1.44 |
| Example | 11 | 3.6 | A | 77.36 | 18.24 | 4.40 | 4 | 421 | 2 | 22 | 22 | 1.00 | 1.78 | 1.48 |
| Example | 12 | 3.9 | A | 64.16 | 18.24 | 17.60 | 1 | 480 | 3 | 16 | 16 | 1.00 | 1.98 | 1.64 |
| Example | 13 | 4.1 | A | 55.36 | 18.24 | 26.40 | 1 | 456 | 3 | 14 | 14 | 1.00 | 2.02 | 1.68 |
| Example | 14 | 3.4 | A | 97.10 | 2.88 | 0.02 | 131 | 398 | 2 | 62 | 32 | 0.52 | 1.44 | 1.37 |
| Example | 15 | 3.5 | A | 96.90 | 2.88 | 0.22 | 13 | 328 | 2 | 58 | 30 | 0.52 | 1.52 | 1.44 |
| Example | 16 | 3.6 | A | 96.02 | 2.88 | 1.10 | 3 | 410 | 1 | 54 | 28 | 0.51 | 1.62 | 1.54 |
| Example | 17 | 3.6 | A | 92.72 | 2.88 | 4.40 | 1 | 304 | 2 | 24 | 11 | 0.47 | 1.74 | 1.65 |
| Example | 18 | 3.4 | A | 69.26 | 30.72 | 0.02 | 1396 | 421 | 2 | 56 | 56 | 1.00 | 1.64 | 1.36 |
| Example | 19 | 3.5 | A | 69.06 | 30.72 | 0.22 | 140 | 491 | 2 | 54 | 54 | 1.00 | 1.72 | 1.43 |
| Example | 20 | 3.6 | A | 68.18 | 30.72 | 1.10 | 28 | 398 | 1 | 50 | 50 | 1.00 | 1.86 | 1.54 |
| Example | 21 | 3.6 | A | 67.08 | 30.72 | 2.20 | 14 | 480 | 1 | 34 | 34 | 1.00 | 1.89 | 1.57 |
| Example | 22 | 3.6 | A | 66.64 | 30.72 | 2.64 | 12 | 456 | 2 | 32 | 30 | 0.94 | 2.23 | 1.85 |
| Example | 23 | 3.4 | A | 78.86 | 21.12 | 0.02 | 960 | 398 | 1 | 23 | 23 | 1.00 | 1.62 | 1.34 |
| Example | 24 | 3.5 | A | 78.66 | 21.12 | 0.22 | 96 | 363 | 1 | 55 | 55 | 1.00 | 1.68 | 1.39 |
| Example | 25 | 3.6 | A | 77.78 | 21.12 | 1.10 | 19 | 398 | 0 | 53 | 53 | 1.00 | 1.82 | 1.51 |
| Example | 26 | 3.6 | A | 76.68 | 21.12 | 2.20 | 10 | 386 | 0 | 33 | 33 | 1.00 | 1.86 | 1.54 |
| Example | 27 | 3.6 | A | 76.24 | 21.12 | 2.64 | 8 | 445 | 1 | 31 | 28 | 0.90 | 2.11 | 1.75 |
| Compar- | 1 | 1.8 | A | 80.66 | 18.24 | 1.10 | 17 | 398 | 6 | 52 | 54 | 1.04 | 3.80 | 3.30 |
| ative | | | | | | | | | | | | | | |
| Example | | | | | | | | | | | | | | |
| Compar- | 2 | 1.9 | A | 80.66 | 18.24 | 1.10 | 17 | 398 | 6 | 52 | 54 | 1.04 | 3.60 | 3.10 |
| ative | | | | | | | | | | | | | | |
| Example | | | | | | | | | | | | | | |

TABLE 6

| | | Oxide Semiconductor Film and Semiconductor Device | | | | | | | | | | | | |
|---|---|---|---|---|---|---|---|---|---|---|---|---|---|---|
| | | Oxygen | | Element Content | | | | | Arcing | Mobility | Mobility | | ΔVth | ΔVth |
| | | Coordination | Crystal- | In | Zn | W | Zn/W | Zr | Frequency | (350° C.) | (450° C.) | Mobility | (350° C.) | (450° C.) |
| | | Number | linity | (at. %) | (at. %) | (at. %) | Ratio | (ppm) | (times) | (cm²/Vs) | (cm²/Vs) | Ratio | (V) | (V) |
| Example | 28 | 3.4 | A | 59.66 | 40.32 | 0.02 | 1833 | 421 | 1 | 48 | 48 | 1.00 | 1.34 | 1.28 |
| Example | 29 | 3.5 | A | 59.46 | 40.32 | 0.22 | 183 | 491 | 1 | 46 | 46 | 1.00 | 1.42 | 1.18 |
| Example | 30 | 3.6 | A | 58.58 | 40.32 | 1.10 | 37 | 398 | 1 | 32 | 32 | 1.00 | 1.64 | 1.36 |
| Example | 31 | 3.6 | A | 57.48 | 40.32 | 2.20 | 18 | 480 | 2 | 30 | 30 | 1.00 | 1.72 | 1.43 |
| Example | 32 | 3.6 | A | 57.04 | 40.32 | 2.64 | 15 | 456 | 2 | 28 | 26 | 0.93 | 1.83 | 1.52 |
| Example | 33 | 3.4 | A | 46.22 | 53.76 | 0.02 | 2444 | 421 | 1 | 32 | 32 | 1.00 | 1.48 | 1.23 |
| Example | 34 | 3.5 | A | 46.02 | 53.76 | 0.22 | 244 | 491 | 1 | 28 | 28 | 1.00 | 1.52 | 1.26 |
| Example | 35 | 3.6 | A | 45.14 | 53.76 | 1.10 | 49 | 398 | 2 | 25 | 25 | 1.00 | 1.67 | 1.39 |
| Example | 36 | 3.6 | A | 44.04 | 53.76 | 2.20 | 24 | 480 | 2 | 22 | 22 | 1.00 | 1.76 | 1.46 |
| Example | 37 | 3.6 | A | 43.60 | 53.76 | 2.64 | 20 | 456 | 2 | 20 | 17 | 0.85 | 1.87 | 1.55 |
| Example | 38 | 3.4 | A | 37.58 | 62.40 | 0.02 | 2836 | 398 | 2 | 16 | 16 | 1.00 | 1.22 | 1.00 |
| Example | 39 | 3.6 | A | 13.38 | 86.40 | 0.22 | 393 | 445 | 4 | 12 | 12 | 1.00 | 1.12 | 1.02 |

The oxide sintered material of either Comparative Example 1 or 2 has the same element content as the oxide sintered material of Example 3, but contains the ZnO crystal phase instead of the In₂(ZnO)ₘO₃ crystal phase (IZ crystal phase). As a result, the amount of pores and the number of abnormal discharges were great in the oxide sintered material of Comparative Example 1 or 2.

Compared with the semiconductor device (TFT) manufactured using the oxide sintered material of Example 3 as the sputtering target, the semiconductor device (TFT) manufactured using the oxide sintered material of Comparative Example 1 or 2 as the sputtering target had a larger ΔVₜₕ in the test of evaluating the reliability under light irradiation, indicating a lower reliability.

It should be understood that the embodiments disclosed herein have been presented for the purpose of illustration and description but not limited in all aspects. It is intended that the scope of the present invention is not limited to the description above but defined by the scope of the claims and encompasses all modifications equivalent in meaning and scope to the claims.

### REFERENCE SIGNS LIST

10, 20, 30: semiconductor device (TFT); 11: substrate; 12: gate electrode; 13: gate insulating film; 14: oxide semiconductor film; 14c: channel part; 14d: drain electrode forming part; 14s: source electrode forming part; 15: source electrode; 16: drain electrode; 17: etch stopper layer; 17a: contact hole; 18: passivation film

1. An oxide sintered material containing indium, tungsten and zinc,
comprising an In₂O₃ crystal phase and an In₂(ZnO)ₘO₃ crystal phase (m represents a natural number), and
an average number of oxygen atoms coordinated to an indium atom being 3 or more and less than 5.5.

2. The oxide sintered material according to claim 1, wherein
a content of the In₂O₃ crystal phase is 10 mass % or more and less than 98 mass %.

3. The oxide sintered material according to claim 1, wherein
a content of the In₂(ZnO)ₘO₃ crystal phase is 1 mass % or more and less than 90 mass %.

4. The oxide sintered material according to claim 1, wherein
the oxide sintered material further comprises a ZnWO₄ crystal phase.

5. The oxide sintered material according to claim 4, wherein
a content of the ZnWO₄ crystal phase is 0.1 mass % or more and less than 10 mass %.

6. The oxide sintered material according to claim 1, wherein
a content of tungsten relative to a total content of indium, tungsten and zinc in the oxide sintered material is greater than 0.01 atom % and smaller than 20 atom %.

7. The oxide sintered material according to claim 1, wherein
a content of zinc relative to a total content of indium, tungsten and zinc in the oxide sintered material is greater than 1.2 atom % and smaller than 60 atom %.

8. The oxide sintered material according to claim 1, wherein
a ratio of a content of zinc relative to a content of tungsten in the oxide sintered material is greater than 1 and smaller than 20000 by atom ratio.

9. The oxide sintered material according to claim 1, wherein
the oxide sintered material further contains zirconium, and
a content of zirconium relative to a total content of indium, tungsten, zinc and zirconium in the oxide sintered material is 0.1 ppm or more and 200 ppm or less by atom ratio.

10. A sputtering target comprising the oxide sintered material according to claim 1.

11. A method of manufacturing a semiconductor device including an oxide semiconductor film, comprising:
preparing the sputtering target according to claim 10; and
forming the oxide semiconductor film by a sputtering method using the sputtering target.

12. An oxide semiconductor film containing indium, tungsten and zinc,
the oxide semiconductor film being amorphous, and
an average number of oxygen atoms coordinated to an indium atom being 2 or more and less than 4.5.

13. The oxide semiconductor film according to claim 12, wherein
a content of tungsten relative to a total content of indium, tungsten and zinc in the oxide semiconductor film is greater than 0.01 atom % and smaller than 20 atom %.

14. The oxide semiconductor film according to claim 12, wherein
a content of zinc relative to a total content of indium, tungsten and zinc in the oxide semiconductor film is greater than 1.2 atom % and smaller than 60 atom %.

15. The oxide semiconductor film according to claim 12, wherein
a ratio of a content of zinc relative to a content of tungsten in the oxide semiconductor film is greater than 1 and smaller than 20000 by atom ratio.

16. The oxide semiconductor film according to claim 12, further containing zirconium, wherein
a content of zirconium relative to a total content of indium, tungsten, zinc and zirconium in the oxide sintered material is 0.1 ppm or more and 2000 ppm or less by atom ratio.

17. A method of manufacturing an oxide sintered material according to claim 1, comprising:
forming the oxide sintered material by sintering a molded body containing indium, tungsten and zinc,
forming the oxide sintered material including placing the molded body for 2 hours or more in an atmosphere having an oxygen concentration greater than that in the air at a first temperature lower than the maximum temperature in forming the oxide sintered material,
the first temperature being 300° C. or more and less than 600° C.
